(19) United States
(12) Patent Application Publication
(10) Pub. No.: US 2017/0025393 A1
(43) Pub. Date: Jan. 26, 2017

(54) THERMALLY ENHANCED FACE-TO-FACE SEMICONDUCTOR ASSEMBLY WITH HEAT SPREADER AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/289,126

(22) Filed: Oct. 8, 2016

Related U.S. Application Data
(63) Continuation-in-part of application No. 15/166,185, filed on May 26, 2016.
(60) Provisional application No. 62/166,771, filed on May 27, 2015.

(51) Int. Cl. H01L 25/065; H01L 23/31; H01L 21/48; H01L 25/00; H01L 21/56; H01L 21/54; H01L 23/367; H01L 23/29

(52) U.S. Cl. CPC H01L 25/0657; H01L 23/3672; H01L 23/3114; H01L 23/3178; H01L 23/293; H01L 25/50; H01L 21/563; H01L 21/54; H01L 21/4882; H01L 2225/06589; H01L 2225/06513; H01L 2225/06586; H01L 2225/06524

(57) ABSTRACT

A face-to-face semiconductor assembly is characterized in that an encapsulated device having a first semiconductor chip surrounded by an array of vertical connecting elements in an encapsulant is stacked on and electrically coupled to a thermally enhanced device having a second semiconductor chip accommodated in a cavity of a thermal board. The first and second semiconductor chips are face-to-face mounted on two opposite sides of a first routing circuitry and is further electrically connected to the vertical connecting elements through the first routing circuitry. The thermal board has a heat spreader to provide thermal dissipation for the second semiconductor chip. The first routing circuitry provides primary fan-out routing for the first and second semiconductor chips, whereas the vertical connecting elements provide electrical contacts for next-level connection.

### CROSS REFERENCE TO RELATED APPLICATIONS

This application is a continuation-in-part of U.S. application Ser. No. 15/166,185 filed May 26, 2016, which claims the priority benefit of U.S. Provisional Application Ser. No. 62/166,771 filed May 27, 2015. The entirety of each of said Applications is incorporated herein by reference.

### FIELD OF THE INVENTION

The present invention relates to a semiconductor assembly and, more particularly, to a semiconductor assembly in which two semiconductor devices are face-to-face mounted together through dual routing circuitries and external contact terminals are provided in one of the devices, and a method of making the same.

### DESCRIPTION OF RELATED ART

Market trends of multimedia devices demand for faster and slimmer designs. One of assembly approaches is to interconnect two chips with “face-to-face” configuration so that the routing distance between the two chips can be the shortest possible. As the stacked chips can talk directly to each other with reduced latency, the assembly's signal integrity and additional power saving capability are greatly improved. As a result, the face-to-face semiconductor assembly offers almost all of the true 3D IC stacking advantages without the need of expensive through-silicon-via (TSV) in the stacked chips. U.S. Patent Application No. 2014/0210107 discloses stacked chip assembly with face-to-face configuration. Since the bottom chip is not protected and has to be thinner than the solder ball(s) for external connection, the assembly is not reliable and cannot be used in practical applications. U.S. Pat. Nos. 8,008,121, 8,519,537 and 8,558,395 disclose various assembly structures having an interposer disposed in between the face-to-face chips. Although there is no TSV in the stacked chips, the TSV in the interposer that serves for circuitry routing between chips induces complicated manufacturing processes, high yield loss and excessive cost. Additionally, as semiconductor devices are susceptible to performance degradation at high operational temperatures, stacking chips with face-to-face configuration without proper heat dissipation would worsen devices' thermal environment and may cause immediate failure during operation.

For the reasons stated above, and for other reasons stated below, an urgent need exists to provide a new face-to-face semiconductor assembly that can address high packaging density, better signal integrity and high thermal dissipation requirements.

### SUMMARY OF THE INVENTION

A primary objective of the present invention is to provide a face-to-face semiconductor assembly in which two semiconductor devices are face-to-face mounted together through dual routing circuitries so as to enhance the interconnect efficiency between the two semiconductor devices, thereby ensuring superior electrical performance of the assembly.

Another objective of the present invention is to provide a face-to-face semiconductor assembly, in which external contact terminals of the assembly are provided in the device through vertical connecting elements so that extra solder balls that surround the peripheral edges of the assembly are not necessary, thereby reducing the dimension of the assembly.

Yet another objective of the present invention is to provide a face-to-face semiconductor assembly in which a thermal board having a heat spreader and a routing circuitry disposed on the heat spreader is attached to a semiconductor chip so that heat from the semiconductor chip can be directly and/or indirectly dissipated through the heat spreader, thereby effectively improving thermal performance of the assembly.

In accordance with the foregoing and other objectives, the present invention provides a thermally enhanced face-to-face semiconductor assembly having an encapsulated device electrically coupled to a thermally enhanced device, wherein the encapsulated device includes a first semiconductor chip, a first routing circuitry, an array of vertical connecting elements and an encapsulant, and the thermally enhanced device includes a second semiconductor chip and a thermal board. In a preferred embodiment, the first semiconductor chip is electrically coupled to a top side of the first routing circuitry and surrounded by the vertical connecting elements and sealed in the encapsulant; the second semiconductor chip is electrically coupled to a bottom side of the first routing circuitry by first bumps and thus is face-to-face electrically connected to the first semiconductor chip through the first routing circuitry; the first routing circuitry provides primary fan-out routing and the shortest interconnection distance between the first semiconductor chip and the second semiconductor chip; and the thermal board is thermally conductible to the second semiconductor chip accommodated in a cavity of the thermal board to provide thermal dissipation for the second semiconductor chip.

In another aspect, the present invention provides a thermally enhanced face-to-face semiconductor assembly with a heat spreader, comprising: an encapsulated device that includes a first semiconductor chip, an encapsulant, an array of vertical connecting elements, and a first routing circuitry disposed on a first surface of the encapsulant, wherein (i) the first semiconductor chip is embedded in the encapsulant and electrically coupled to the first routing circuitry, and (ii) the vertical connecting elements are laterally covered by the encapsulant and surround the first semiconductor chip, wherein the vertical connecting elements are electrically coupled to the first routing circuitry and extend to or extend beyond a second surface of the encapsulant opposite to the first surface; and a thermally enhanced device that includes a heat spreader, a second routing circuitry disposed over the heat spreader, and a second semiconductor chip thermally conductible to the heat spreader by a thermally conductive contact element; wherein the encapsulated device is stacked over the thermally enhanced device, with the second semiconductor chip electrically coupled to and spaced from the first routing circuitry by an array of first bumps, and with the second routing circuitry electrically coupled to and spaced from the first routing circuitry by an array of second bumps.

In yet another aspect, the present invention provides another thermally enhanced face-to-face semiconductor assembly with a heat spreader, comprising: an encapsulated device that includes a first semiconductor chip, an encapsulant, an array of vertical connecting elements, and a first routing circuitry disposed on a first surface of the encapsulant, wherein (i) the first semiconductor chip is embedded in the encapsulant and electrically coupled to the first routing circuitry, and (ii) the vertical connecting elements are laterally covered by the encapsulant and surround the first semiconductor chip, wherein the vertical connecting elements are electrically coupled to the first routing circuitry and extend to or extend beyond a second surface of the encapsulant opposite to the first surface; and a thermally enhanced device that includes a heat spreader and a second semiconductor chip thermally conductible to the heat spreader by a thermally conductive contact element and located in a cavity of the heat spreader, wherein the encapsulated device is stacked over the thermally enhanced device, with the second semiconductor chip electrically coupled to and spaced from the first routing circuitry by an array of bumps.

In yet another aspect, the present invention provides a method of making a thermally enhanced face-to-face semiconductor assembly with a heat spreader, comprising steps of: providing an encapsulated device that includes a first semiconductor chip, an encapsulant, an array of vertical connecting elements and a first routing circuitry disposed on a first surface of the encapsulant, wherein (i) the first semiconductor chip is embedded in the encapsulant and electrically coupled to the first routing circuitry, and (ii) the vertical connecting elements surround the first semiconductor chip and are electrically coupled to the first routing circuitry; electrically coupling a second semiconductor chip to the first routing circuitry of the encapsulated device through an array of first bumps at the first routing circuitry; providing a thermal board that includes a heat spreader; and stacking the encapsulated device over the thermal board, with the second semiconductor chip thermally conductible to the heat spreader by a thermally conductive contact element.

Unless specifically indicated or using the term “then” between steps, or steps necessarily occurring in a certain order, the sequence of the above-mentioned steps is not limited to that set forth above and may be changed or reordered according to desired design.

The face-to-face semiconductor assembly and the method of making the same according to the present invention have numerous advantages. For instance, face-to-face electrically coupling the first and second semiconductor chips to both opposite sides of the first routing circuitry can offer the shortest interconnect distance between the first and second semiconductor chips. Forming the vertical connecting elements in the encapsulant is particularly advantageous as the vertical connecting elements around the first semiconductor chip can provide electrical connections between both opposite sides of the encaspulant and denser and smaller solder balls can be mounted on the top side of the encapsulant for external connection so as to avoid the use of large external solder balls to span the height of the encapsulated device. Additionally, inserting the second semiconductor chip into the cavity of the thermal board is beneficial as the heat spreader of the thermal board can provide thermal dissipation for the second semiconductor chip and serve as a support platform for the encapsulated device stacked thereon.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIG. 1 is a cross-sectional view of the structure with routing traces formed on a sacrificial carrier in accordance with the first embodiment of the present invention;

FIG. 2 is a cross-sectional view of the structure of FIG. 1 further provided with a first dielectric layer and first via openings in accordance with the first embodiment of the present invention;

FIG. 3 is a cross-sectional view of the structure of FIG. 2 further provided with first conductive traces in accordance with the first embodiment of the present invention;

FIG. 4 is a cross-sectional view of the structure of FIG. 3 further provided with first semiconductor chip in accordance with the first embodiment of the present invention;

FIG. 5 is a cross-sectional view of the structure of FIG. 4 further provided with first solder balls in accordance with the first embodiment of the present invention;

FIG. 6 is a cross-sectional view of the structure of FIG. 5 further provided with an encapsulant in accordance with the first embodiment of the present invention;

FIG. 7 is a cross-sectional view of the structure of FIG. 6 further provided with openings in accordance with the first embodiment of the present invention;

FIG. 8 is a cross-sectional view of the structure of FIG. 7 after removal of the sacrificial carrier in accordance with the first embodiment of the present invention;

FIG. 9 is a cross-sectional view of a heat spreader in accordance with the first embodiment of the present invention;

FIG. 10 is a cross-sectional view of the structure of FIG. 9 further provided with a second dielectric layer and second via openings in accordance with the first embodiment of the present invention;

FIG. 11 is a cross-sectional view of the structure of FIG. 10 further provided with second conductive traces in accordance with the first embodiment of the present invention;

FIG. 12 is a cross-sectional view of the structure of FIG. 11 further provided with a third dielectric layer and third via openings in accordance with the first embodiment of the present invention;

FIG. 13 is a cross-sectional view of the structure of FIG. 12 further provided with third conductive traces in accordance with the first embodiment of the present invention;

FIG. 14 is a cross-sectional view of the structure of FIG. 13 further provided with a second semiconductor chip in accordance with the first embodiment of the present invention;

FIG. 15 is a cross-sectional view of the structure of FIG. 14 further provided with first and second bumps in accordance with the first embodiment of the present invention;

FIG. 16 is a cross-sectional view showing the step of stacking the structure of FIG. 8 on the structure of FIG. 15 in accordance with the first embodiment of the present invention;

FIG. 17 is a cross-sectional view of the structure of FIG. 8 electrically coupled to the structure of FIG. 15 in accordance with the first embodiment of the present invention;

FIG. 18 is a cross-sectional view of the structure of FIG. 17 further provided with second solder balls to finish the fabrication of a face-to-face semiconductor assembly in accordance with the first embodiment of the present invention;

FIG. 19 is a cross-sectional view of another aspect of face-to-face semiconductor assembly in accordance with the first embodiment of the present invention;

FIG. 20 is a cross-sectional view of the structure of FIG. 4 further provided with solder balls in accordance with the second embodiment of the present invention;

FIG. 21 is a cross-sectional view of the structure of FIG. 20 further provided with a heat spreader in accordance with the second embodiment of the present invention;

FIG. 22 is a cross-sectional view of the structure of FIG. 21 further provided with an encapsulant in accordance with the second embodiment of the present invention;

FIG. 23 is a cross-sectional view of the structure of FIG. 22 after removal of a top portion of the encapsulant in accordance with the second embodiment of the present invention;

FIG. 24 is a cross-sectional view of the structure of FIG. 23 after removal of the sacrificial carrier in accordance with the second embodiment of the present invention;

FIG. 25 is a cross-sectional view showing the step of stacking the structure of FIG. 24 on the structure of FIG. 15 in accordance with the second embodiment of the present invention;

FIG. 26 is a cross-sectional view of the structure of FIG. 24 electrically coupled to the structure of FIG. 15 to finish the fabrication of a face-to-face semiconductor assembly in accordance with the second embodiment of the present invention;

FIG. 27 is a cross-sectional view of another aspect of face-to-face semiconductor assembly in accordance with the second embodiment of the present invention;

FIG. 28 is a cross-sectional view of the structure of FIG. 4 further provided with an encapsulant in accordance with the third embodiment of the present invention;

FIG. 29 is a cross-sectional view of the structure of FIG. 28 further provided with via openings in accordance with the third embodiment of the present invention;

FIG. 30 is a cross-sectional view of the structure of FIG. 29 further provided with conductive vias and exterior conductive traces in accordance with the third embodiment of the present invention;

FIG. 31 is a cross-sectional view of the structure of FIG. 30 further provided with a solder mask in accordance with the third embodiment of the present invention;

FIG. 32 is a cross-sectional view of the structure of FIG. 31 after removal of the sacrificial carrier in accordance with the third embodiment of the present invention;

FIG. 33 is a cross-sectional view of the structure of FIG. 32 further provided with a second semiconductor chip in accordance with the third embodiment of the present invention;

FIG. 34 is a cross-sectional view showing the step of stacking the structure of FIG. 33 on the structure of FIG. 13 in accordance with the third embodiment of the present invention;

FIG. 35 is a cross-sectional view of the structure of FIG. 33 mounted on the structure of FIG. 13 to finish the fabrication of a face-to-face semiconductor assembly in accordance with the third embodiment of the present invention;

FIG. 36 is a cross-sectional view of another aspect of face-to-face semiconductor assembly in accordance with the third embodiment of the present invention;

FIG. 37 is a cross-sectional view of yet another aspect of face-to-face semiconductor assembly in accordance with the third embodiment of the present invention;

FIG. 38 is a cross-sectional view of the structure with a first routing circuitry formed on a sacrificial carrier in accordance with the fourth embodiment of the present invention;

FIG. 39 is a cross-sectional view of the structure of FIG. 38 further provided with metal pillars in accordance with the fourth embodiment of the present invention;

FIG. 40 is a cross-sectional view of the structure of FIG. 39 further provided with a first semiconductor chip in accordance with the fourth embodiment of the present invention;

FIG. 41 is a cross-sectional view of the structure of FIG. 40 further provided with an encapsulant in accordance with the fourth embodiment of the present invention;

FIG. 42 is a cross-sectional view of the structure of FIG. 41 after removal of a top portion of the encapsulant in accordance with the fourth embodiment of the present invention;

FIG. 43 is a cross-sectional view of the structure of FIG. 42 further provided with an external routing circuitry and a solder mask in accordance with the fourth embodiment of the present invention;

FIG. 44 is a cross-sectional view of the structure of FIG. 43 after removal of the sacrificial carrier in accordance with the fourth embodiment of the present invention;

FIG. 45 is a cross-sectional view of the structure of FIG. 44 further provided with a second semiconductor chip in accordance with the fourth embodiment of the present invention;

FIG. 46 is a cross-sectional view of the structure with a second dielectric layer provided on a heat spreader in accordance with the fourth embodiment of the present invention;

FIG. 47 is a cross-sectional view of the structure of FIG. 46 further provided with second conductive traces in accordance with the fourth embodiment of the present invention;

FIG. 48 is a cross-sectional view of the structure of FIG. 47 further provided with a third dielectric layer and third via openings in accordance with the fourth embodiment of the present invention;

FIG. 49 is a cross-sectional view of the structure of FIG. 48 further provided with third conductive traces in accordance with the fourth embodiment of the present invention;

FIG. 50 is a cross-sectional view showing the step of stacking the structure of FIG. 45 on the structure of FIG. 49 in accordance with the fourth embodiment of the present invention;

FIG. 51 is a cross-sectional view of the structure of FIG. 45 mounted on the structure of FIG. 49 to finish the fabrication of a face-to-face semiconductor assembly in accordance with the fourth embodiment of the present invention;

FIG. 52 is a cross-sectional view of a face-to-face semiconductor assembly in accordance with the fifth embodiment of the present invention;

FIG. 53 is a cross-sectional view of another aspect of face-to-face semiconductor assembly in accordance with the fifth embodiment of the present invention;

FIG. 54 is a cross-sectional view of yet another aspect of face-to-face semiconductor assembly in accordance with the fifth embodiment of the present invention; and

FIG. 55 is a cross-sectional view of a face-to-face semiconductor assembly in accordance with the sixth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

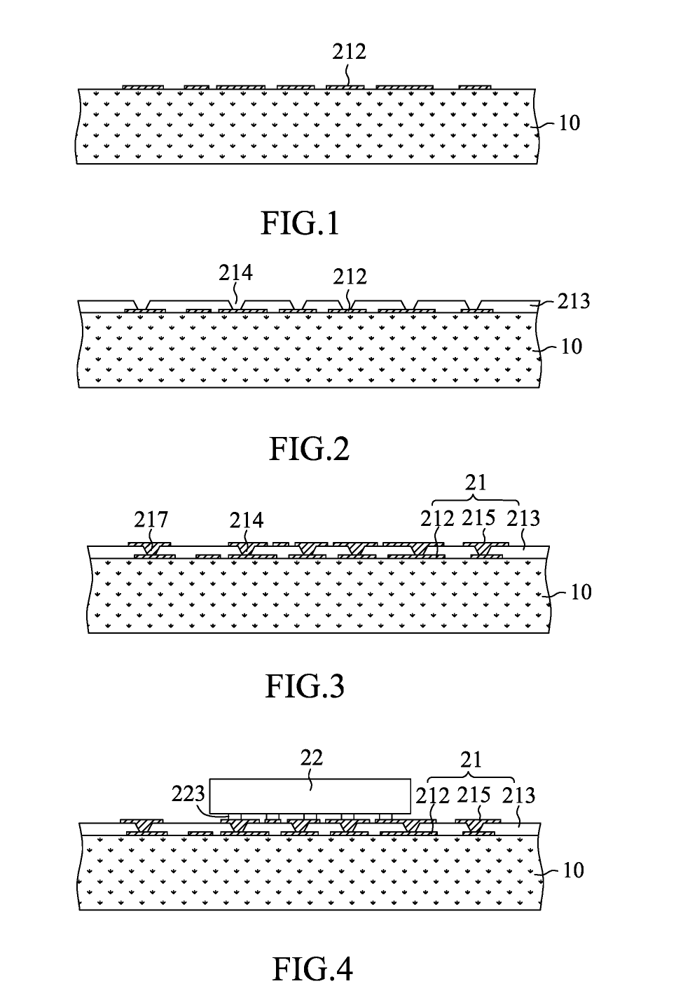

FIGS. 1-18 are schematic views showing a method of making a face-to-face semiconductor assembly that includes a first routing circuitry 21, a first semiconductor chip 22, an array of vertical connecting elements 24, an encapsulant 25, a thermal board 31 and a second semiconductor chip 36 in accordance with the first embodiment of the present invention.

FIG. 1 is a cross-sectional view of the structure with routing traces 212 formed on a sacrificial carrier 10 by metal deposition and metal patterning process. In this illustration, the sacrificial carrier 10 is a single-layer structure. The sacrificial carrier 10 typically is made of copper, aluminum, iron, nickel, tin, stainless steel, silicon, or other metals or alloys, but any other conductive or non-conductive material also may be used. In this embodiment, the sacrificial carrier 10 is made of an iron-based material. The routing traces 212 typically are made of copper and can be pattern deposited by numerous techniques, such as electroplating, electroless plating, evaporating, sputtering or their combinations, or be thin-film deposited followed by a metal patterning process. For a conductive sacrificial carrier 10, the routing traces 212 are deposited typically by plating of metal. The metal patterning techniques include wet etching, electro-chemical etching, laser-assist etching, and their combinations with an etch mask (not shown) thereon that defines the routing traces 212.

FIG. 2 is a cross-sectional view of the structure with a first dielectric layer 213 on the sacrificial carrier 10 as well as the routing traces 212 and first via openings 214 in the first dielectric layer 213. The first dielectric layer 213 is deposited typically by lamination or coating, and contacts and covers and extends laterally on the sacrificial carrier 10 and the routing traces 212 from above. The first dielectric layer 213 typically has a thickness of 50 microns, and can be made of epoxy resin, glass-epoxy, polyimide, or the like. After the deposition of the first dielectric layer 213, the first via openings 214 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The first via openings 214 extend through the first dielectric layer 213 and are aligned with selected portions of the routing traces 212.

Referring now to FIG. 3, first conductive traces 215 are formed on the first dielectric layer 213 by metal deposition and metal patterning process. The first conductive traces 215 extend from the routing traces 212 in the upward direction, fill up the first via openings 214 to form first metallized vias 217 in direct contact with the routing traces 212, and extend laterally on the first dielectric layer 213. As a result, the first conductive traces 215 can provide horizontal signal routing in both the X and Y directions and vertical routing through the first via openings 214 and serve as electrical connections for the routing traces 212.

The first conductive traces 215 can be deposited as a single layer or multiple layers by any of numerous techniques, such as electroplating, electroless plating, evaporating, sputtering, or their combinations. For instance, they can be deposited by first dipping the structure in an activator solution to render the first dielectric layer 213 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 215 by any of numerous techniques such as wet etching, electro-chemical etching, laser-assist etching, or their combinations, with an etch mask (not shown) thereon that defines the first conductive traces 215.

At this stage, the formation of a first routing circuitry 21 on the sacrificial carrier 10 is accomplished. In this illustration, the first routing circuitry 21 is a multi-layered buildup circuitry and includes routing traces 212, a first dielectric layer 213 and first conductive traces 215.

FIG. 4 is a cross-sectional view of the structure with a first semiconductor chip 22 electrically coupled to the first routing circuitry 21. The first semiconductor chip 22, illustrated as a bare chip, can be electrically coupled to the first conductive traces 215 of the first routing circuitry 21 using bumps 223 in contact with the first semiconductor chip 22 and the first routing circuitry 21 by thermal compression, solder reflow or thermosonic bonding.

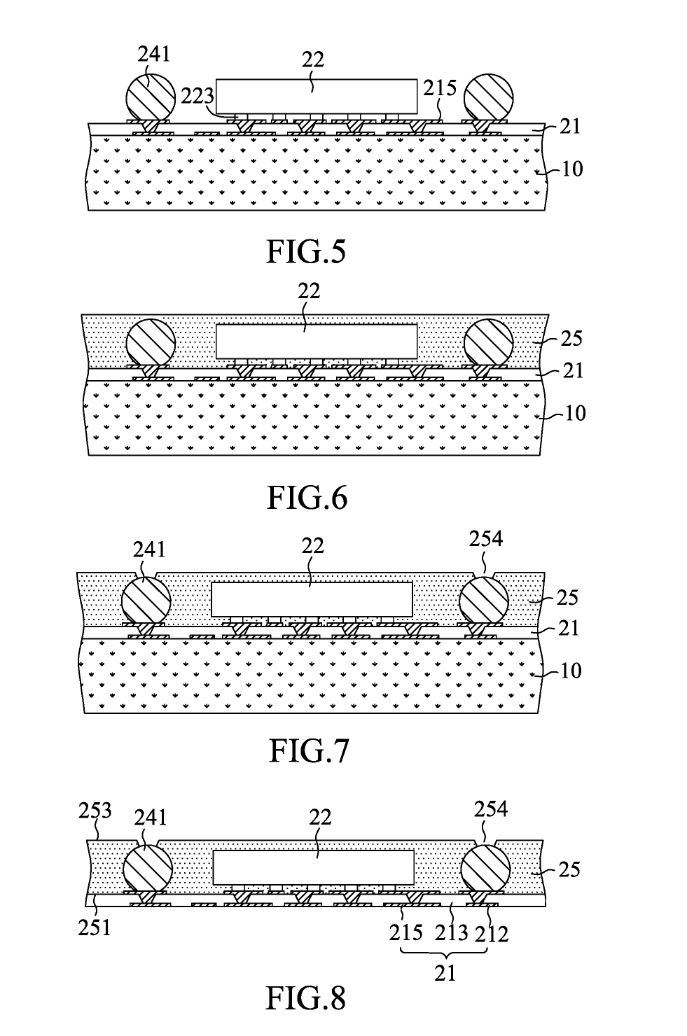

FIG. 5 is a cross-sectional view of the structure with first solder balls 241 on the first routing circuitry 21. The first solder balls 241 are electrically connected to and contact the first conductive traces 215 of the first routing circuitry 21.

FIG. 6 is a cross-sectional view of the structure with an encapsulant 25 on the first routing circuitry 21, the first semiconductor chip 22 and the first solder balls 241 by, for example, resin-glass lamination, resin-glass coating or molding. The encapsulant 25 covers the first routing circuitry 21, the first semiconductor chip 22 and the first solder balls 241 from above and surrounds and conformally coats and covers sidewalls of the first semiconductor chip 22 and the first solder balls 241.

FIG. 7 is a cross-sectional view of the structure provided with openings 254 in the encapsulant 25. The openings 254 are aligned with the first solder balls 241 to expose selected portions of the first solder balls 241 from above.

FIG. 8 is a cross-sectional view of the structure after removal of the sacrificial carrier 10. The sacrificial carrier 10 can be removed to expose the first routing circuitry 21 from below by numerous techniques, such as wet chemical etching using acidic solution (e.g., ferric chloride, copper sulfate solutions), or alkaline solution (e g, ammonia solution), electro-chemical etching, or mechanical process such as a drill or end mill followed by chemical etching. In this embodiment, the sacrificial carrier 10 made of an iron-based material is removed by a chemical etching solution that is selective between copper and iron so as to prevent the copper routing traces 212 from being etched during removal of the sacrificial carrier 10. As a result, the first routing circuitry 21 adjacent to the first surface 251 of the encapsulant 25 and the first solder balls 241 exposed from the second surface 253 of the encapsulant 25 can provide electrical contacts for next-level connection.

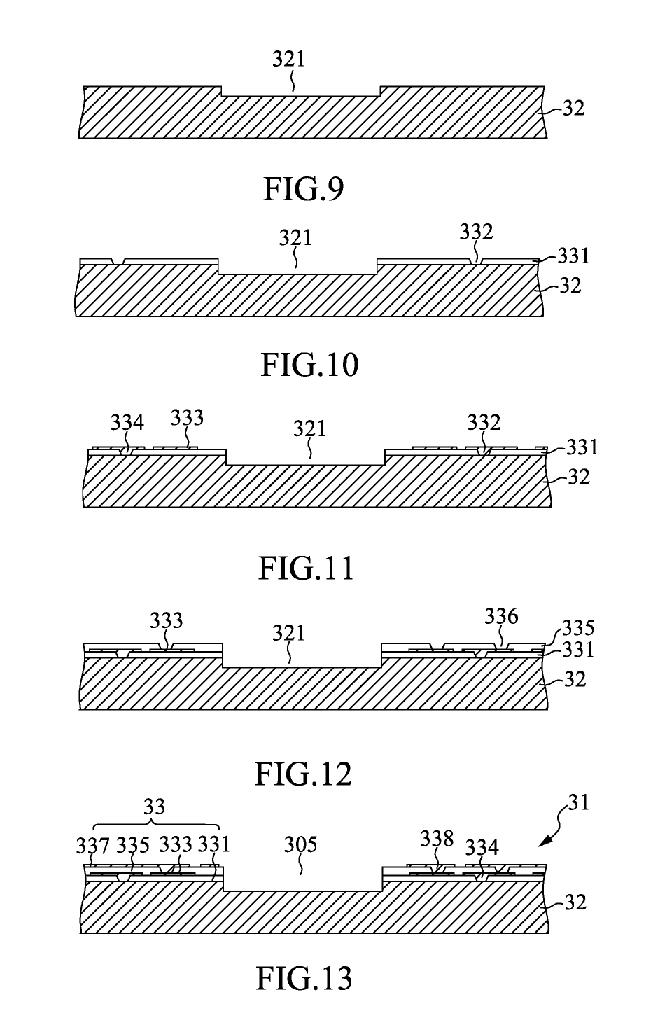

FIG. 9 is a cross-sectional view of a heat spreader 32. The heat spreader 32 can be made of any material with high thermal conductivity, such as copper, aluminum, stainless steel, silicon, ceramic, graphite or other metals or alloys, and is formed with a recess 321. The thickness of the heat spreader 32 can range from 0.5 to 2.0 mm. In this embodiment, the heat spreader 32 has a thickness of 1.0 mm.

FIG. 10 is a cross-sectional view of the structure with a second dielectric layer 331 laminated/coated on a selected portion of the heat spreader 32 outside of the recess 321 from above and second via openings 332 in the second dielectric layer 331. The second dielectric layer 331 contacts the heat spreader 32 and can be formed of epoxy resin, glass-epoxy, polyimide, or the like, and typically has a thickness of 50 microns. The second via openings 332 extend through the second dielectric layer 331 to expose selected portions of the heat spreader 32 from above. Like the first via openings 214, the second via openings 332 can be formed by any of numerous techniques, such as laser drilling, plasma etching and photolithography and typically have a diameter of 50 microns.

Referring now to FIG. 11, second conductive traces 333 are formed on the second dielectric layer 331 by metal deposition and metal patterning process. The second conductive traces 333 extend from the heat spreader 32 in the upward direction, fill up the second via openings 332 to form second metallized vias 334 in direct contact with the heat spreader 32, and extend laterally on the second dielectric layer 331.

FIG. 12 is a cross-sectional view of the structure with a third dielectric layer 335 laminated/coated on the second dielectric layer 331 and the second conductive traces 333 from above and third via openings 336 in the third dielectric layer 335. The third dielectric layer 335 contacts the second dielectric layer 331 and the second conductive traces 333. The third dielectric layer 335 can be formed of epoxy resin, glass-epoxy, polyimide, or the like, and typically has a thickness of 50 microns. The third via openings 336 extend through the third dielectric layer 335 to expose selected portions of the second conductive traces 333 from above. Like the first via openings 214 and the second via openings 332, the third via openings 336 can be formed by any of numerous techniques, such as laser drilling, plasma etching and photolithography and typically have a diameter of 50 microns.

FIG. 13 is a cross-sectional view of the structure provided with third conductive traces 337 on the third dielectric layer 335 by metal deposition and metal patterning process. The third conductive traces 337 extend from the second conductive traces 333 in the upward direction, fill up the third via openings 336 to form third metallized vias 338 in direct contact with the second conductive traces 333, and extend laterally on the third dielectric layer 335.

At this stage, a thermal board 31 having a cavity 305 is accomplished and includes a heat spreader 32 and a second routing circuitry 33. In this illustration, the second routing circuitry 33 is a multi-layered buildup circuitry that includes a second dielectric layer 331, second conductive traces 333, a third dielectric layer 335 and third conductive traces 337, and is electrically coupled to the heat spreader 32 through the second metallized vias 334 for ground connection. The cavity 305 extends through the second routing circuitry 33 to expose a selected portion of the heat spreader 32 from above.

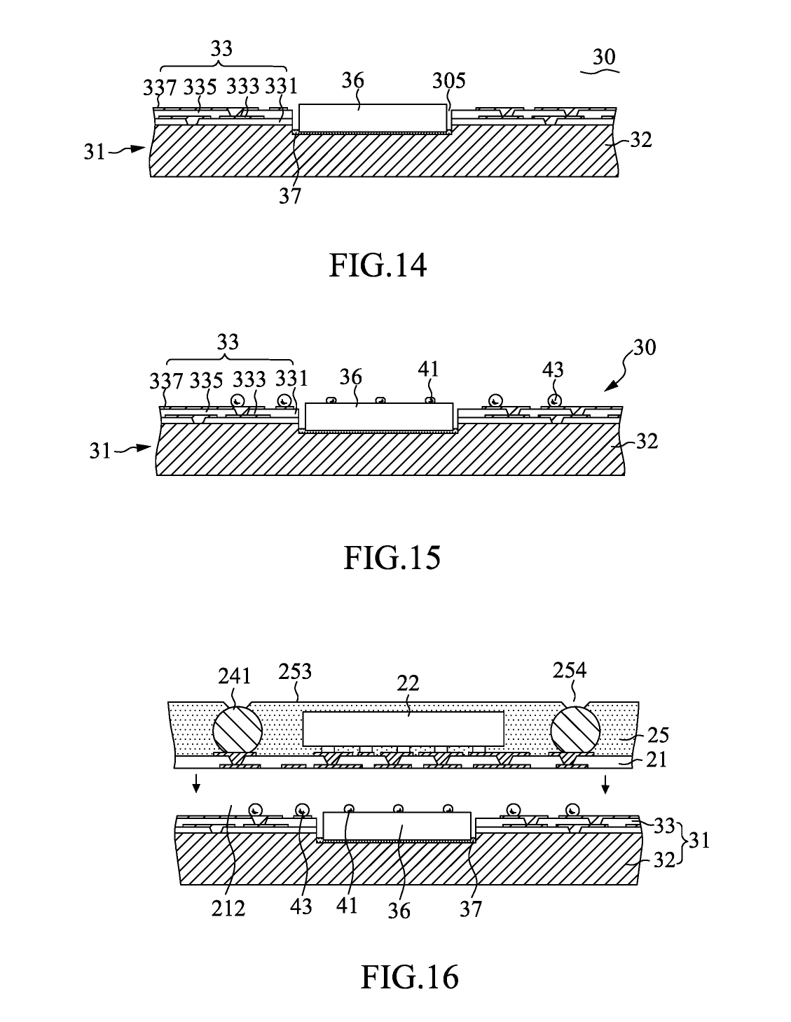

FIG. 14 is a cross-sectional view of the structure with a second semiconductor chip 36 attached to the thermal board 31. The second semiconductor chip 36, illustrated as a bare chip, is face-up inserted into the cavity 305 of the thermal board 31 and thermally conductible to the heat spreader 32 of the thermal board 31 by a thermally conductive contact element 37. The thermally conductive contact element 37 may be made of solder or organic resin having blended metal particles. At this stage, a thermally enhanced device 30 is accomplished and includes a heat spreader 32, a second routing circuitry 33 and a second semiconductor chip 36.

FIG. 15 is a cross-sectional view of the structure with first bumps 41 and second bumps 43 mounted on the thermally enhanced device 30. The first bumps 41 and the second bumps 43 contact and are electrically coupled to the second semiconductor chip 36 and the second routing circuitry 33 of the thermal board 31, respectively.

FIG. 16 is a cross-sectional view showing the step of stacking the structure of FIG. 8 on the thermally enhanced device 30 of FIG. 15. In this illustration, the first semiconductor chip 22 is placed face-down, whereas the second semiconductor chip 36 is placed face-up.

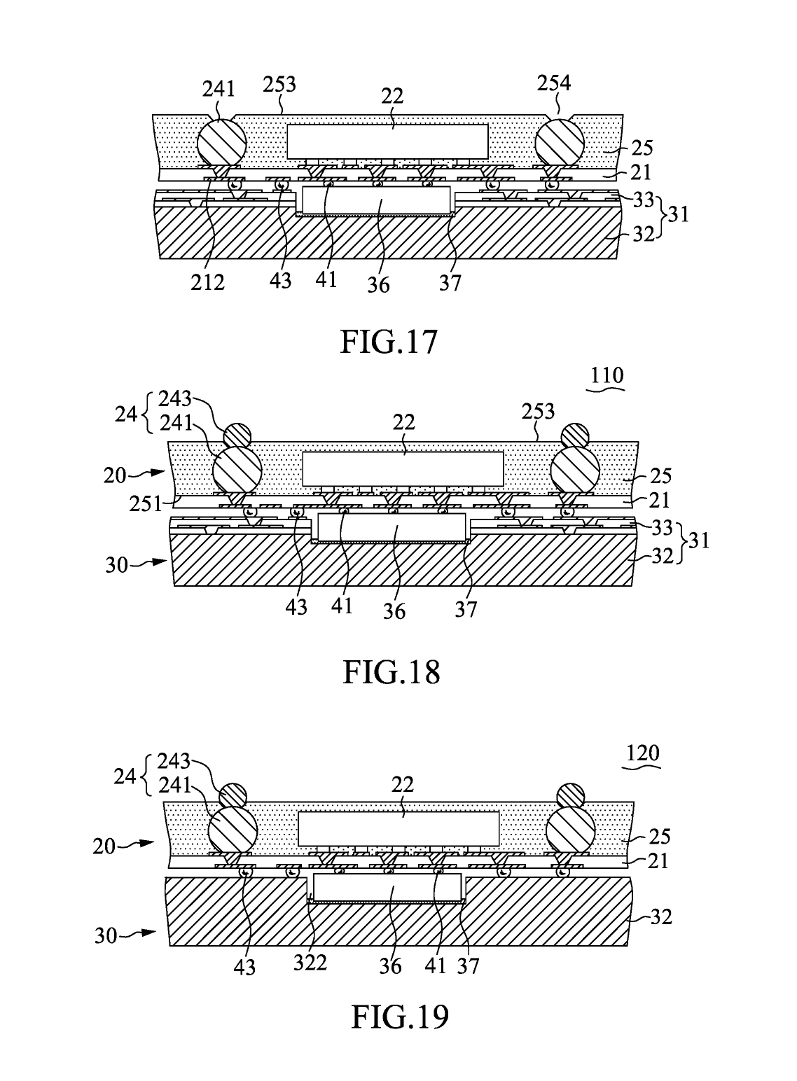

FIG. 17 is a cross-sectional view of the structure with the second semiconductor chip 36 and the second routing circuitry 33 electrically coupled to the first routing circuitry 21. The first bumps 41 and the second bumps 43 contact and are electrically coupled to the routing traces 212 of the first routing circuitry 21 to provide electrical connections between the first routing circuitry 21 and the second semiconductor chip 36 and between the first routing circuitry 21 and the second routing circuitry 33.

FIG. 18 is a cross-sectional view of the structure provided with second solder balls 243 mounted on the first solder balls 241. The second solder balls 243 fill up the openings 254 of the encapsulant 25 and contact the first solder balls 241. As a result, the combination of the first solder balls 241 and the second solder balls 243 can serve as vertical connecting elements 24 that extend from the first routing circuitry 21 beyond the second surface 253 of the encapsulant 25 in the upward direction.

Accordingly, as shown in FIG. 17, a face-to-face semiconductor assembly 110 is accomplished and includes an encapsulated device 20 and a thermally enhanced device 30. The encapsulated device 20 is stacked over and electrically coupled to the thermally enhanced device 30 by an array of first bumps 41 and an array of second bumps 43. In this illustration, the encapsulated device 20 includes a first routing circuitry 21, a first semiconductor chip 22, an array of vertical connecting elements 24 and an encapsulant 25, whereas the thermally enhanced device 30 includes a heat spreader 32, a second routing circuitry 33 and a second semiconductor chip 36.

The first semiconductor chip 22 is flip-chip electrically coupled to the first routing circuitry 21 and embedded in the encapsulant 25. The vertical connecting elements 24 surround the first semiconductor chip 22 and are electrically coupled to the first routing circuitry 21 and laterally covered by the encapsulant 25. The second semiconductor chip 36 is thermally conductible to the heat spreader 32 and flip-chip electrically coupled to and spaced from the first routing circuitry 21 by the first bumps 41. As such, the first routing circuitry 21 offers primary fan-out routing and the shortest interconnection distance between the first semiconductor chip 22 and the second semiconductor chip 36. The second routing circuitry 33 is disposed over and grounded to the heat spreader 32 and electrically coupled to and spaced from the first routing circuitry 21 by the second bumps 43.

FIG. 19 is a cross-sectional view of another aspect of face-to-face semiconductor assembly 120 without second routing circuitry between the first routing circuitry 21 and the heat spreader 32. The face-to-face semiconductor assembly 120 is similar to that illustrated in FIG. 18, except that the thermally enhanced device 30 has no second routing circuitry on the heat spreader 32. In this aspect, the second semiconductor chip 36 is located in a cavity 322 of the heat spreader 32, and optionally the heat spreader 32 is electrically coupled to the first routing circuitry 21 for ground connection by the second bumps 43 in contact with the first routing circuitry 21 and the heat spreader 32.

### Embodiment 2

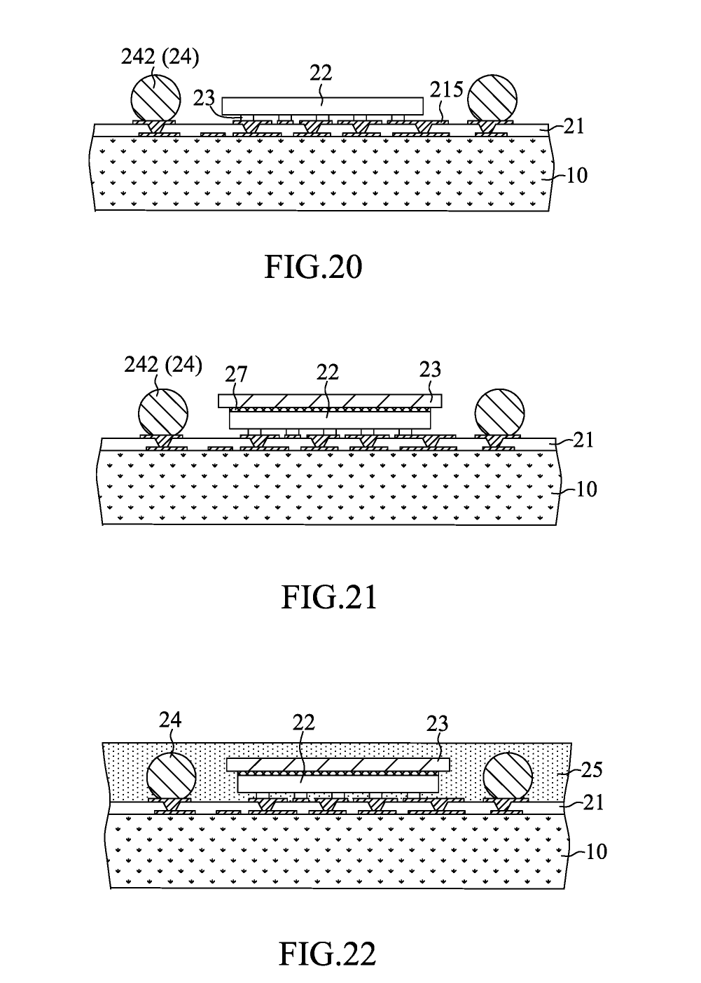

FIGS. 20-26 are schematic views showing a method of making a face-to-face semiconductor assembly with another heat spreader attached to the first semiconductor chip in accordance with the second embodiment of the present invention.

For purposes of brevity, any description in Embodiment 1 above is incorporated herein insofar as the same is applicable, and the same description need not be repeated.

FIG. 20 is a cross-sectional view of the structure with solder balls 242 mounted on the first routing circuitry 21 of FIG. 4. The solder balls 242 are placed at the peripheral area of the exterior surface of the first routing circuitry 21 and contact the first conductive traces 215 to serve as vertical connecting elements 24 around the first semiconductor chip 22.

FIG. 21 is a cross-sectional view of the structure with a heat spreader 23 attached on the first semiconductor chip 22. The heat spreader 23 can be made of any material with high thermal conductivity, such as metal, alloy, silicon, ceramic or graphite. The heat spreader 23 is attached on an inactive surface of the first semiconductor chip 22 using a thermally conductive contact element 27.

FIG. 22 is a cross-sectional view of the structure with an encapsulant 25 on the first routing circuitry 21, the vertical connecting elements 24 and the heat spreader 23. The encapsulant 25 covers the first routing circuitry 21, the vertical connecting elements 24 and the heat spreader 23 from above and surrounds and conformally coats and covers sidewalls of the first semiconductor chip 22, the vertical connecting elements 24 and the heat spreader 23.

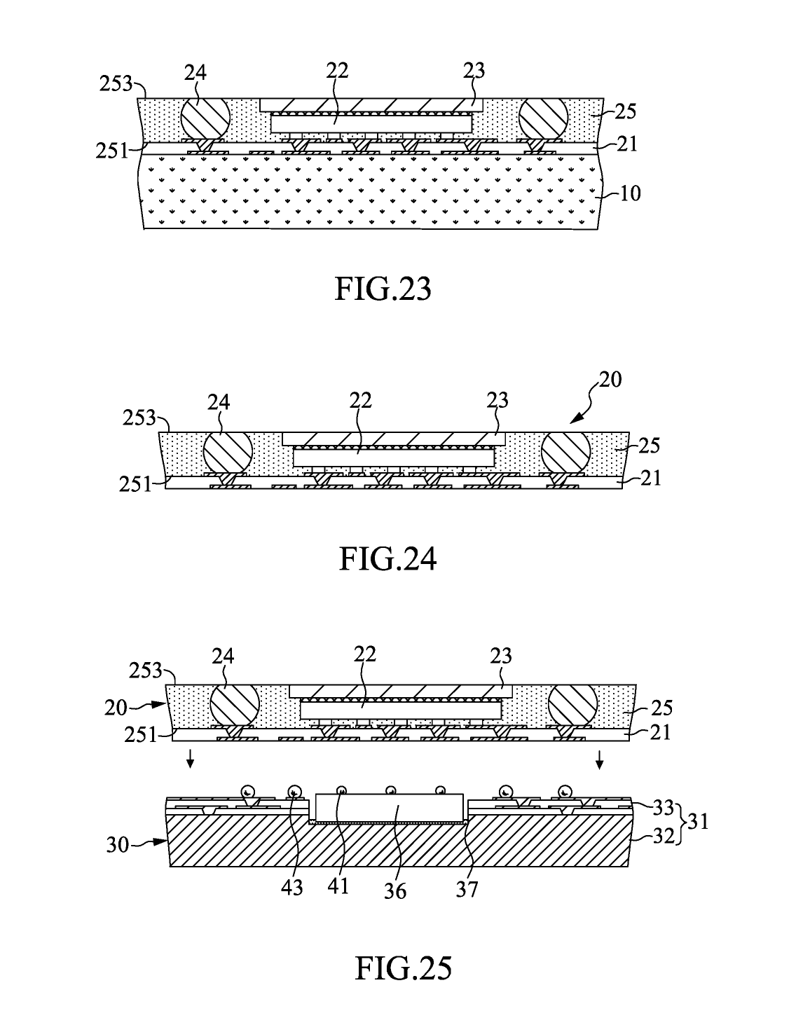

FIG. 23 is a cross-sectional view of the structure with the vertical connecting elements 24 and the heat spreader 23 exposed from above by removing a top portion of the encapsulant 25. In this illustration, the encapsulant 25 has a first surface 251 adjacent to the first routing circuitry 21 and a second surface 253 substantially coplanar with the exposed surfaces of the vertical connecting elements 24 and the heat spreader 23.

FIG. 24 is a cross-sectional view of the structure with the first routing circuitry 21 exposed below by removing the sacrificial carrier 10. As a result, an encapsulated device 20 is accomplished and includes a first routing circuitry 21, a first semiconductor chip 22, an array of vertical connecting elements 24, an encapsulant 25 and a heat spreader 23.

FIG. 25 is a cross-sectional view showing the step of stacking the encapsulated device 20 of FIG. 24 on the thermally enhanced device 30 of FIG. 15. In this illustration, the first semiconductor chip 22 is placed face-down, whereas the second semiconductor chip 36 is placed face-up.

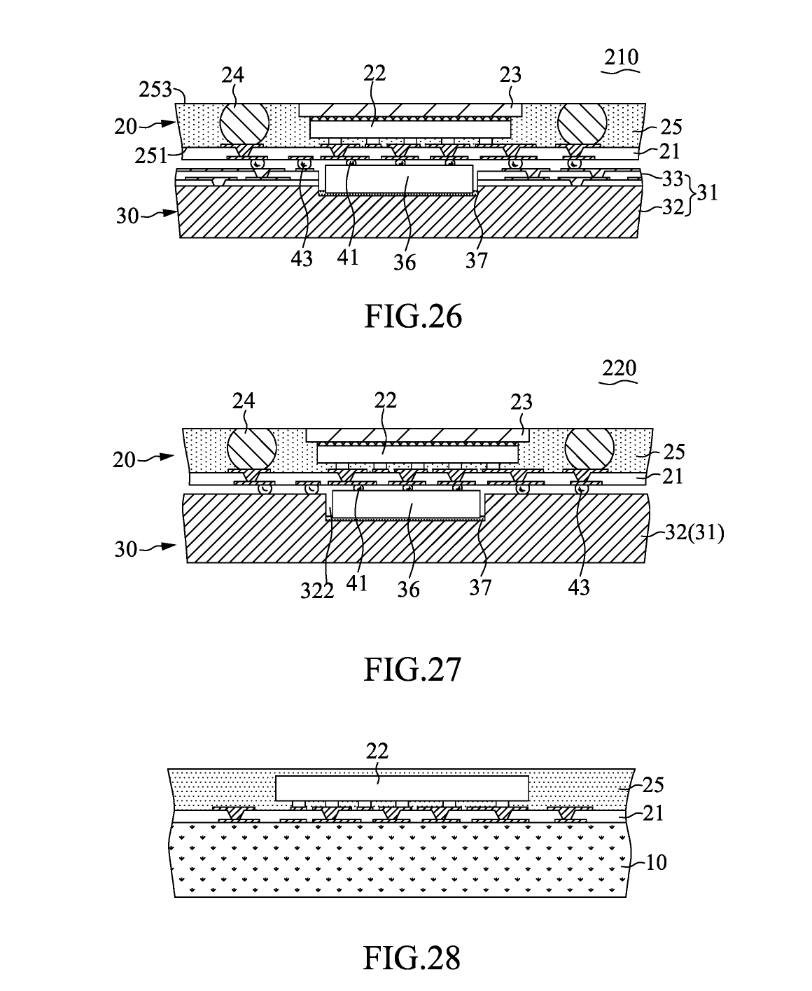

FIG. 26 is a cross-sectional view of the structure with the encapsulated device 20 electrically coupled to the thermally enhanced device 30. The second semiconductor chip 36 and the second routing circuitry 33 of the thermally enhanced device 30 are electrically coupled to the first routing circuitry 21 of the encapsulated device 20 by the first bumps 41 and the second bumps 43, respectively.

Accordingly, as shown in FIG. 26, a face-to-face semiconductor assembly 210 is accomplished and includes an encapsulated device 20 and a thermally enhanced device 30. In this illustration, the encapsulated device 20 includes a first routing circuitry 21, a first semiconductor chip 22, an array of vertical connecting elements 24, an encapsulant 25 and a heat spreader 23, whereas the thermally enhanced device 30 includes a heat spreader 32, a second routing circuitry 33 and a second semiconductor chip 36.

The first semiconductor chip 22 is embedded in the encapsulant 25, whereas the second semiconductor chip 36 is accommodated in the cavity 305 of the thermal board 31. The first semiconductor chip 22 and the second semiconductor chip 36 are face-to-face electrically coupled to each other through the first routing circuitry 21 therebetween and thermally conductible to the heat spreaders 23, 32, respectively. The vertical connecting elements 24 extend from the first routing circuitry 21 to the second surface 253 of the encapsulant 25 and surround the first semiconductor chip 22 to provide electrical contacts for next-level connection from the second surface 253 of the encapsulant 25. The second routing circuitry 33 laterally surrounds the second semiconductor chip 36 and is electrically coupled to the heat spreader 32 and the first routing circuitry 21 for ground connection.

FIG. 27 is a cross-sectional view of another aspect of face-to-face semiconductor assembly 220 without second routing circuitry between the first routing circuitry 21 and the heat spreader 32. The face-to-face semiconductor assembly 220 is similar to that illustrated in FIG. 26, except that the thermal board 31 has no second routing circuitry on the heat spreader 32. In this aspect, the second semiconductor chip 36 is located in a cavity 322 of the heat spreader 32, and optionally the heat spreader 32 is electrically coupled to the first routing circuitry 21 for ground connection by the second bumps 43 in contact with the first routing circuitry 21 and the heat spreader 32.

### Embodiment 3

FIGS. 28-35 are schematic views showing a method of making a face-to-face semiconductor assembly with an external routing circuitry in accordance with the third embodiment of the present invention.

For purposes of brevity, any description in Embodiments above is incorporated herein insofar as the same is applicable, and the same description need not be repeated.

FIG. 28 is a cross-sectional view of the structure with an encapsulant 25 on the first routing circuitry 21 and the first semiconductor chip 22 of FIG. 4. The encapsulant 25 covers the first routing circuitry 21 and the first semiconductor chip 22 from above and surrounds and conformally coats and covers sidewalls of the first semiconductor chip 22.

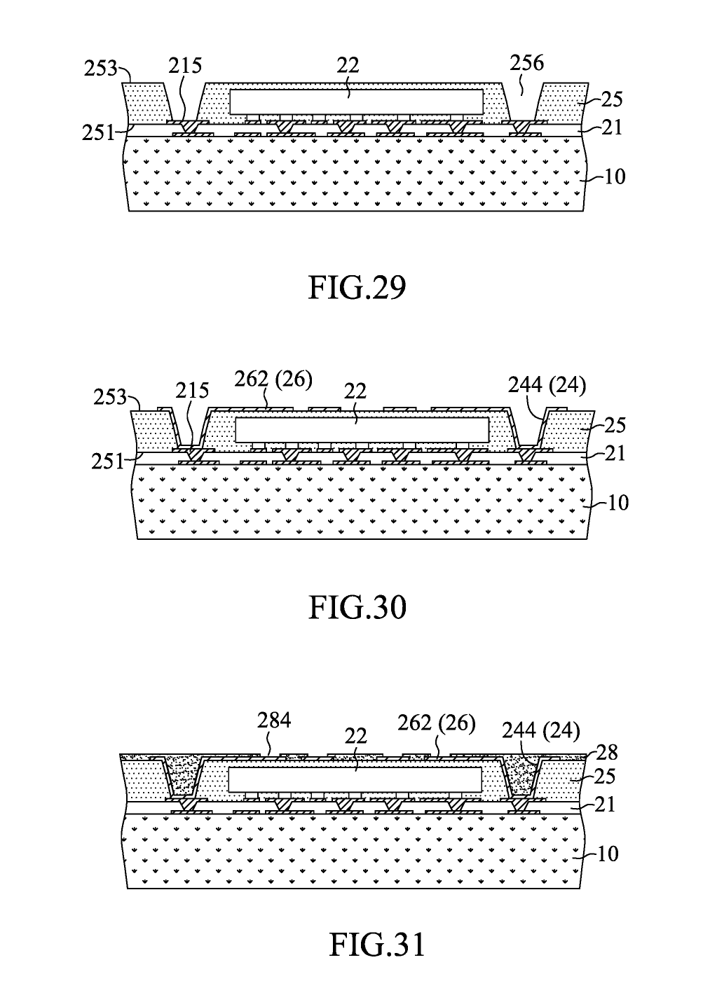

FIG. 29 is a cross-sectional view of the structure with via openings 256 in the encapsulant 25. The via openings 256 are aligned with selected portions of the first conductive traces 215 of the first routing circuitry 21 and extend through the encapsulant 25 between the first surface 251 and the second surface 253 of the encapsulant 25.

FIG. 30 is a cross-sectional view of the structure provided with conductive vias 244 in the via openings 256 and the exterior conductive traces 262 on the encapsulant 25. The conductive vias 244 are formed by metal deposition in the via openings 256 and contact the first conductive traces 215 of the first routing circuitry 21 to serve as vertical connecting elements 24 around the first semiconductor chip 22. The exterior conductive traces 262 are formed on the second surface 253 of the encapsulant 25 by metal deposition and metal patterning process and electrically coupled to the conductive vias 244.

At this stage, the formation of an external routing circuitry 26 on the second surface 253 of the encapsulant 25 is accomplished. In this illustration, the external routing circuitry 26 includes exterior conductive traces 262 that laterally extend on the second surface 253 of the encapsulant 25 and contact and are electrically coupled to the vertical connecting elements 24 in the encapsulant 25.

FIG. 31 is a cross-sectional view of the structure provided with a solder mask 28 on the encapsulant 25 and the external routing circuitry 26 and in remaining spaces of the via openings 256. The solder mask 28 covers the encapsulant 25 and the external routing circuitry 26 from above and fills up the remaining spaces of the via openings 256. The solder mask 28 has openings 284 to expose selected portions of the exterior conductive traces 262 from above.

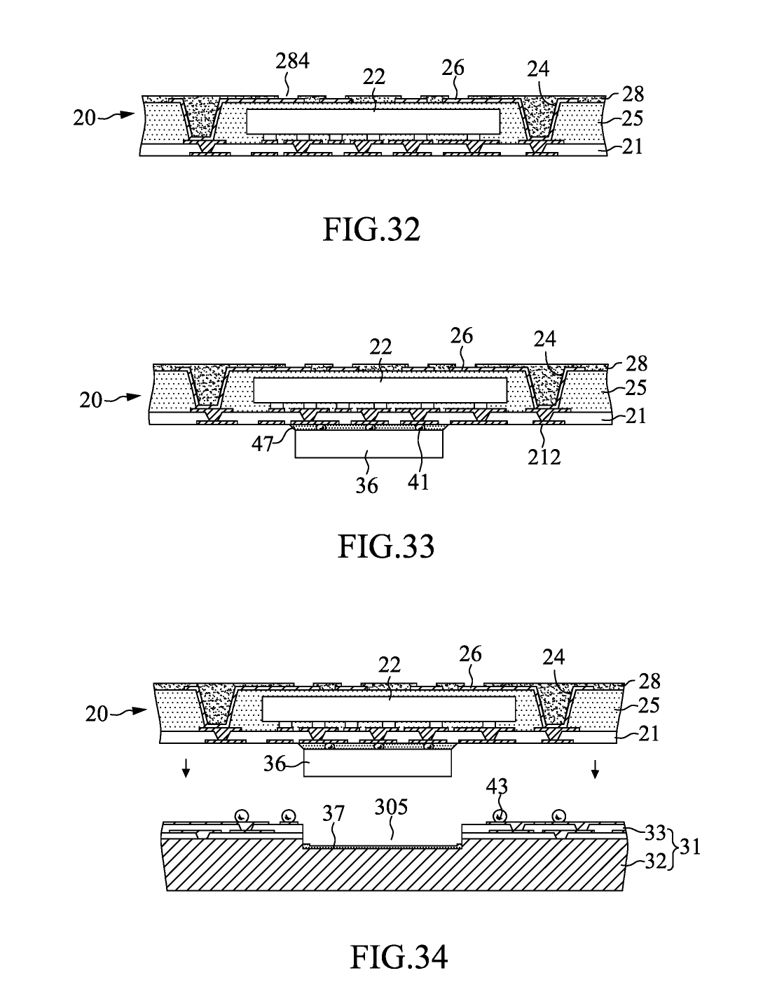

FIG. 32 is a cross-sectional view of the structure with the first routing circuitry 21 exposed below by removing the sacrificial carrier 10. As a result, an encapsulated device 20 is accomplished and includes a first routing circuitry 21, a first semiconductor chip 22, an array of vertical connecting elements 24, an encapsulant 25, an external routing circuitry 26 and a solder mask 28.

FIG. 33 is a cross-sectional view of the structure with a second semiconductor chip 36 electrically coupled to the first routing circuitry 21. The second semiconductor chip 36 is flip-chip mounted to the first routing circuitry 21 by an array of first bumps 41 in contact with the routing traces 212 of the first routing circuitry 21. Optionally, underfill 47 can be further provided to fill the gap between the first routing circuitry 21 and the second semiconductor chip 36.

FIG. 34 is a cross-sectional view showing the step of stacking the structure of FIG. 33 on the thermal board 31 of FIG. 13. Before the stacking process, a thermally conductive contact element 37 is dispensed in the cavity 305 of the thermal board 31, and an array of second bumps 43 are mounted on the second routing circuitry 33 of the thermal board 31.

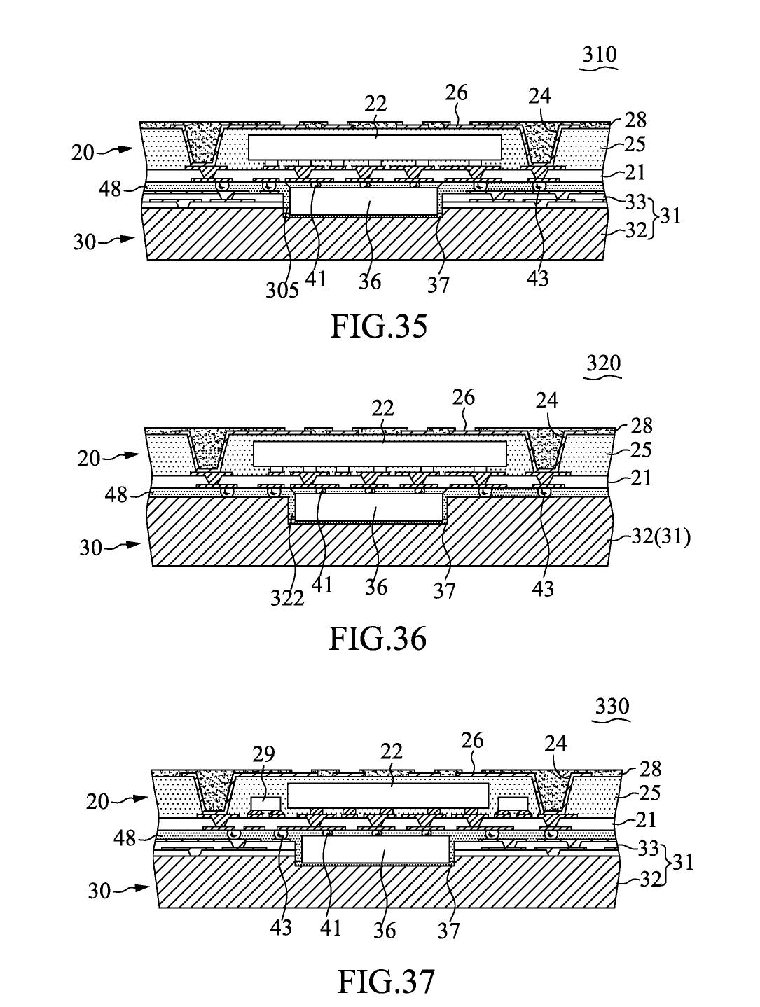

FIG. 35 is a cross-sectional view of the structure with the thermal board 31 attached to the second semiconductor chip 36 and electrically coupled to the first routing circuitry 21. The second semiconductor chip 36 is inserted into the cavity 305 of the thermal board 31 and thermally conductible to the heat spreader 32 of the thermal board 31 by the thermally conductive contact element 37. The second routing circuitry 33 of the thermal board 31 is electrically coupled to the first routing circuitry 21 by the second bumps 43. Optionally, a resin 48 can be further provided to fill in the space between the first routing circuitry 21 and the second routing circuitry 33 and between the first routing circuitry 21 and the second semiconductor chip 36, and fill up the gap located in the cavity 305 between the second semiconductor chip 36 and sidewalls of the cavity 305.

Accordingly, as shown in FIG. 35, a face-to-face semiconductor assembly 310 is accomplished and includes an encapsulated device 20 and a thermally enhanced device 30. In this illustration, the encapsulated device 20 includes a first routing circuitry 21, a first semiconductor chip 22, an array of vertical connecting elements 24, an encapsulant 25, an external routing circuitry 26 and a solder mask 28, whereas the thermally enhanced device 30 includes a heat spreader 32, a second routing circuitry 33 and a second semiconductor chip 36.

The first semiconductor chip 22 and the second semiconductor chip 36 are disposed at two opposite sides of the first routing circuitry 21 and face-to-face electrically connected to each other through the first routing circuitry 21 therebetween. The first semiconductor chip 22 is embedded in the encapsulant 25 and surrounded by the vertical connecting elements 24, whereas the second semiconductor chip 36 is accommodated in the cavity 305 of the thermal board 31 and thermally conductible to the heat spreader 32. The second routing circuitry 33 of the thermal board 31 is electrically coupled to the heat spreader 32 and the first routing circuitry 21 for ground connection. The first routing circuitry 21 is electrically connected to the external routing circuitry 26 by the vertical connecting elements 24 in the encapsulant 25.

FIG. 36 is a cross-sectional view of another aspect of face-to-face semiconductor assembly 320 without second routing circuitry between the first routing circuitry 21 and the heat spreader 32. The face-to-face semiconductor assembly 320 is similar to that illustrated in FIG. 35, except that the thermal board 31 has no second routing circuitry on the heat spreader 32. In this aspect, the second semiconductor chip 36 is located in a cavity 322 of the heat spreader 32, and optionally the heat spreader 32 is electrically coupled to the first routing circuitry 21 for ground connection by the second bumps 43 in contact with the first routing circuitry 21 and the heat spreader 32.

FIG. 37 is a cross-sectional view of yet another aspect of face-to-face semiconductor assembly 330 with electronic components 29 embedded in the encapsulant 25. In this aspect, the face-to-face semiconductor assembly 330 is manufactured in a manner similar to that illustrated in face-to-face semiconductor assembly 310, except that the encapsulated device 20 further includes electronic components 29, such as integrated passive component or decoupling capacitor, electrically coupled to the first routing circuitry 21 and sealed by the encapsulant 25.

### Embodiment 4

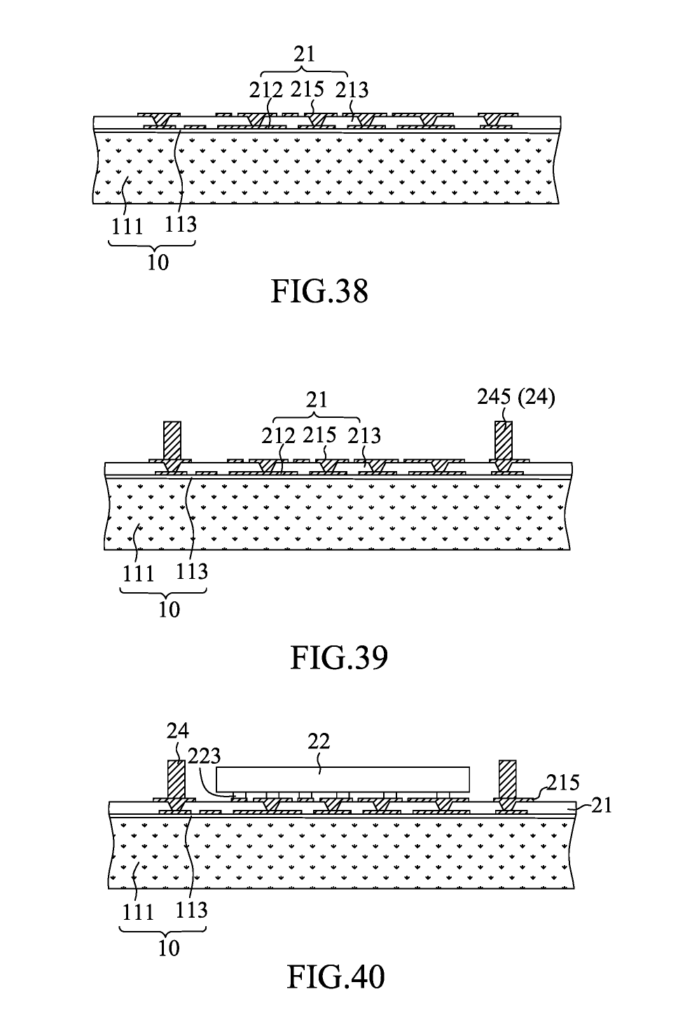

FIGS. 38-51 are schematic views showing a method of making a face-to-face semiconductor assembly having metal pillar as the vertical connecting elements in accordance with the fourth embodiment of the present invention.

For purposes of brevity, any description in Embodiments above is incorporated herein insofar as the same is applicable, and the same description need not be repeated.

FIG. 38 is a cross-sectional view of the structure with a first routing circuitry 21 detachably adhered over a sacrificial carrier 10. In this illustration, the sacrificial carrier 10 is a double-layer structure and includes a support sheet 111 and a barrier layer 113 deposited on the support sheet 111. The first routing circuitry 21 is formed on the barrier layer 113 by the steps illustrated in FIGS. 1-3. The barrier layer 113 can have a thickness of 0.001 to 0.1 mm and may be a metal layer that is inactive against chemical etching during chemical removal of the support sheet 111 and can be removed without affecting the routing traces 212. For instance, the barrier layer 113 may be made of tin or nickel when the support sheet 111 and the routing traces 212 are made of copper. Further, in addition to metal materials, the barrier layer 113 can also be a dielectric layer such as a peelable laminate film. In this embodiment, the support sheet 111 is a copper sheet, and the barrier layer 113 is a nickel layer of 5 microns in thickness.

FIG. 39 is a cross-sectional view of the structure with an array of metal pillars 245 deposited on the first routing circuitry 21. The metal pillars 245 are located at the peripheral area of the exterior surface of the first routing circuitry 21 and contact the first conductive traces 215 to serve as vertical connecting elements 24.

FIG. 40 is a cross-sectional view of the structure with a first semiconductor chip 22 electrically coupled to the first routing circuitry 21 from above. The first semiconductor chip 22 is electrically coupled to the first routing circuitry 21 using bumps 223 and surrounded by the vertical connecting elements 24.

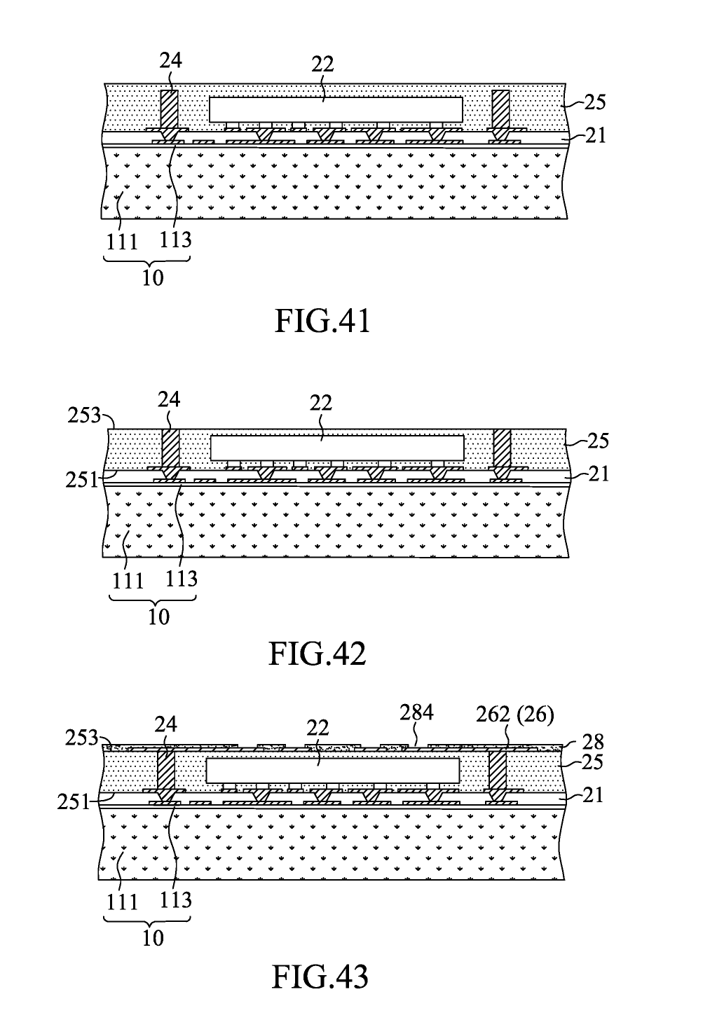

FIG. 41 is a cross-sectional view of the structure with an encapsulant 25 on the first routing circuitry 21, the first semiconductor chip 22 and the vertical connecting elements 24. The encapsulant 25 covers the first routing circuitry 21, the first semiconductor chip 22 and the vertical connecting elements 24 from above and surrounds and conformally coats and covers sidewalls of the first semiconductor chip 22 and the vertical connecting elements 24.

FIG. 42 is a cross-sectional view of the structure with the vertical connecting elements 24 exposed from above by removing a top portion of the encapsulant 25. In this illustration, the encapsulant 25 has a first surface 251 adjacent to the first routing circuitry 21 and a second surface 253 substantially coplanar with the exposed surface of the vertical connecting elements 24.

FIG. 43 is a cross-sectional view of the structure provided with exterior conductive traces 262 on the encapsulant 25 and a solder mask 28 on the encapsulant 25 and the exterior conductive traces 262. The exterior conductive traces 262 laterally extend on the second surface 253 of the encapsulant 25 and contact the vertical connecting elements 24. At this stage, the formation of an external routing circuitry 26 on the second surface 253 of the encapsulant 25 is accomplished. The solder mask 28 covers the encapsulant 25 and the external routing circuitry 26 from above and has openings 284 to expose selected portions of the exterior conductive traces 262.

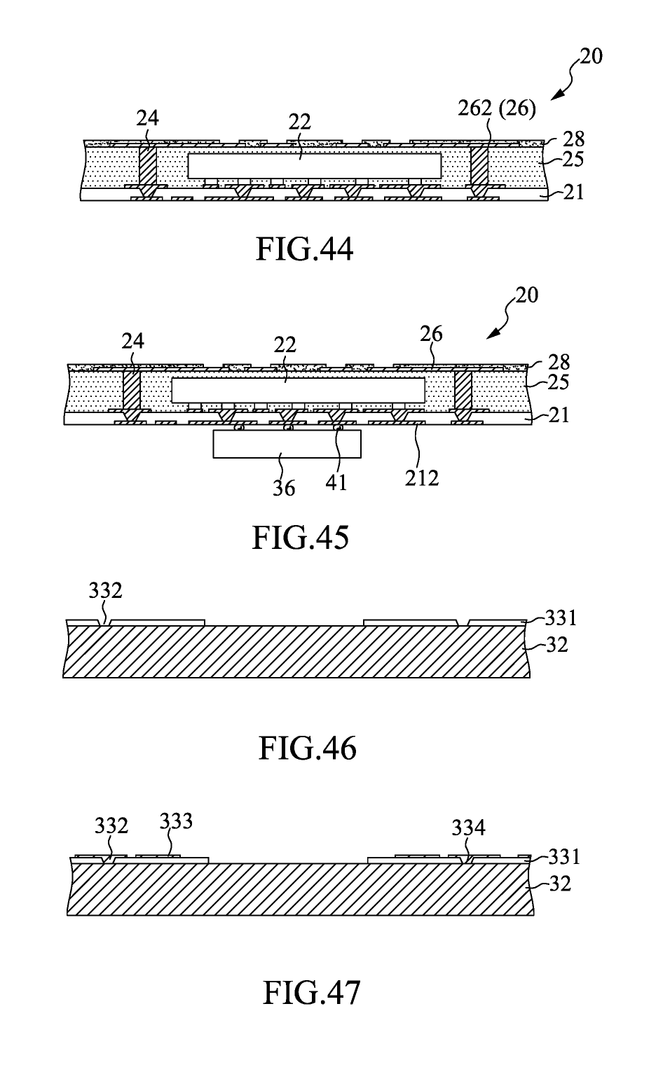

FIG. 44 is a cross-sectional view of the structure after removal of the sacrificial carrier 10. The first routing circuitry 21 is exposed from below by removing the support sheet 111 made of copper using an alkaline etching solution and then removing the barrier layer 113 made of nickel using an acidic etching solution. In another aspect, if the barrier layer 113 is a peelable laminate film, the barrier layer 113 can be removed by mechanical peeling or plasma ashing. As a result, an encapsulated device 20 is accomplished and includes a first routing circuitry 21, a first semiconductor chip 22, an array of vertical connecting elements 24, an encapsulant 25, an external routing circuitry 26 and a solder mask 28.

FIG. 45 is a cross-sectional view of the structure with a second semiconductor chip 36 electrically coupled to the first routing circuitry 21. The second semiconductor chip 36 is flip-chip mounted to the first routing circuitry 21 by an array of first bumps 41 in contact with the routing traces 212 of the first routing circuitry 21.

FIG. 46 is a cross-sectional view of the structure with a second dielectric layer 331 laminated/coated on a heat spreader 32 and second via openings 332 in the second dielectric layer 331. The second dielectric layer 331 contacts and covers a selected portion of the heat spreader 32 from above. The second via openings 332 extend through the second dielectric layer 331 to expose selected portions of the heat spreader 32 from above.

FIG. 47 is a cross-sectional view of the structure provided with second conductive traces 333 on the second dielectric layer 331 by metal deposition and metal patterning process. The second conductive traces 333 extend from the heat spreader 32 in the upward direction, fill up the second via openings 332 to form second metallized vias 334 in direct contact with the heat spreader 32, and extend laterally on the second dielectric layer 331.

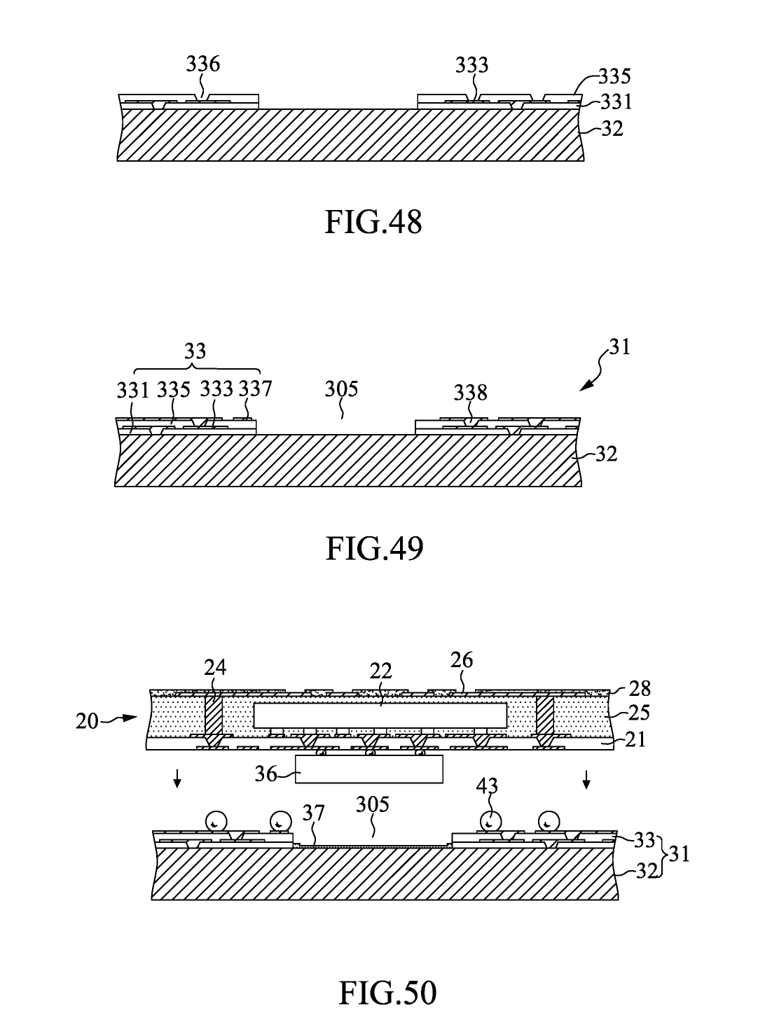

FIG. 48 is a cross-sectional view of the structure with a third dielectric layer 335 laminated/coated on the second dielectric layer 331/second conductive traces 333 and third via openings 336 in the third dielectric layer 335. The third dielectric layer 335 contacts and covers the second dielectric layer 331/second conductive traces 333 from above. The third via openings 336 extend through the third dielectric layer 335 to expose selected portions of the second conductive traces 333 from above.

FIG. 49 is a cross-sectional view of the structure provided with third conductive traces 337 on the third dielectric layer 335 by metal deposition and metal patterning process. The third conductive traces 337 extend from the second conductive traces 333 in the upward direction, fill up the third via openings 336 to form third conductive vias 338 in direct contact with the second conductive traces 333, and extend laterally on the third dielectric layer 335.

At this stage, a thermal board 31 having a cavity 305 is accomplished and includes a heat spreader 32 and a second routing circuitry 33. The cavity 305 extends through the second routing circuitry 33, and a selected portion of the heat spreader 32 is exposed from the cavity 305 from above. In this illustration, the second routing circuitry 33 includes a second dielectric layer 331, second conductive traces 333, a third dielectric layer 335 and third conductive traces 337.

FIG. 50 is a cross-sectional view showing the step of stacking the structure of FIG. 45 on the thermal board 31 of FIG. 49. Before the stacking process, a thermally conductive contact element 37 is dispensed in the cavity 305 of the thermal board 31, and an array of second bumps 43 are mounted on the second routing circuitry 33 of the thermal board 31.

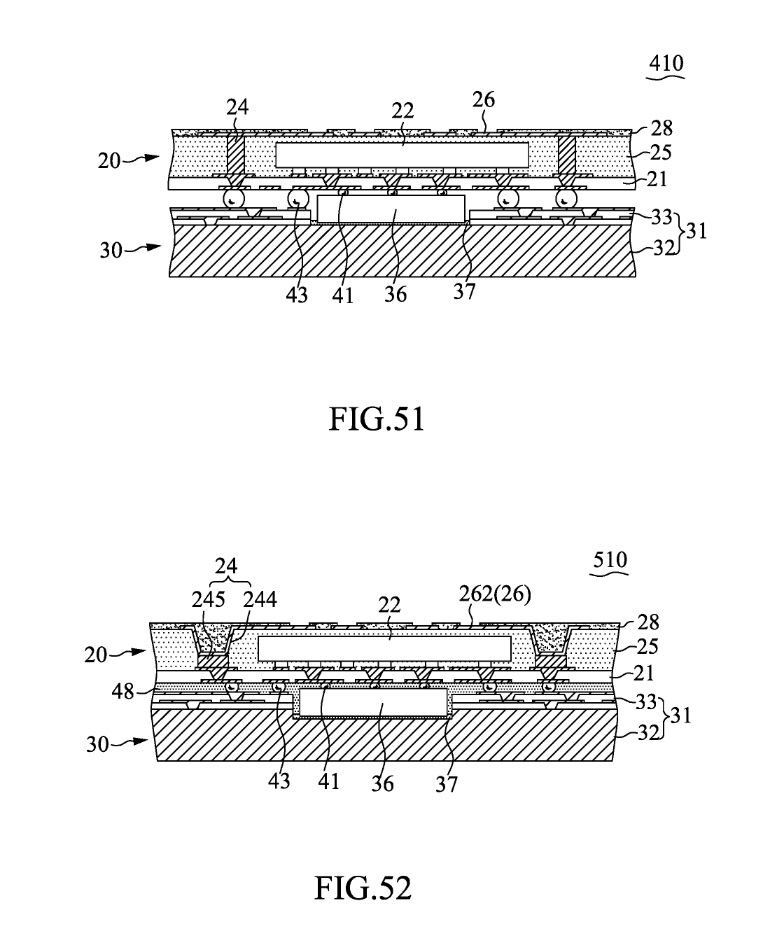

FIG. 51 is a cross-sectional view of the structure with the encapsulated device 20 and the second semiconductor chip 36 mounted to the thermal board 31. The second semiconductor chip 36 is inserted into the cavity 305 of the thermal board 31 and thermally conductible to the heat spreader 32 of the thermal board 31 by the thermally conductive contact element 37. The second routing circuitry 33 of the thermal board 31 is electrically coupled to the first routing circuitry 21 by the second bumps 43.

Accordingly, as shown in FIG. 51, a face-to-face semiconductor assembly 410 is accomplished and includes an encapsulated device 20 and a thermally enhanced device 30. In this illustration, the encapsulated device 20 includes a first routing circuitry 21, a first semiconductor chip 22, an array of vertical connecting elements 24, an encapsulant 25, an external routing circuitry 26 and a solder mask 28, whereas the thermally enhanced device 30 includes a heat spreader 32, a second routing circuitry 33 and a second semiconductor chip 36.

The first routing circuitry 21 provides the shortest interconnection distance between the first semiconductor chip 22 and the second semiconductor chip 36. The vertical connecting elements 24 sealed in the encapsulant 25 provide electrical connection between the first routing circuitry 21 and the external routing circuitry 26 at two opposite sides of the encapsulant 25. The heat spreader 32 provides a thermal dissipation pathway for the second semiconductor chip 36. The second routing circuitry 33 is electrically coupled to the heat spreader 32 and the first routing circuitry 21 for ground connection.

### Embodiment 5

FIGS. 52-54 are cross-sectional views of other face-to-face semiconductor assemblies in accordance with the fifth embodiment of the present invention.

In this embodiment, the face-to-face semiconductor assemblies 510, 520, 530 are manufactured in a manner similar to that illustrated in Embodiment 3, except that the vertical connecting elements 24 are formed in different configurations.

In the face-to-face semiconductor assembly 510 of FIG. 52, the vertical connecting elements 24 include a combination of conductive vias 244 and metal pillars 245. The metal pillars 245 contact the first conductive traces 215, and the conductive vias 244 extend from the metal pillars 245 to the exterior conductive traces 262.

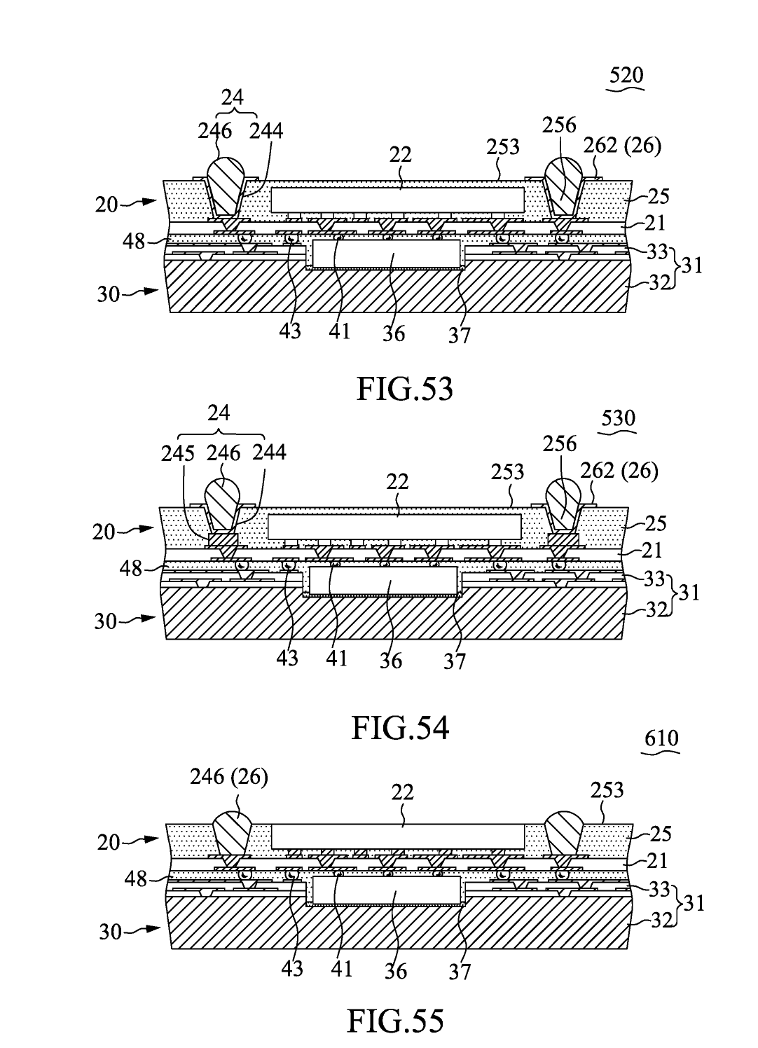

In the face-to-face semiconductor assembly 520 of FIG. 53, the vertical connecting elements 24 include a combination of conductive vias 244 and solder balls 246. The conductive vias 244 extend from the first routing circuitry 21 to the exterior conductive traces 262, and the solder balls 246 contact the conductive vias 244 and fill up the remaining space of the via openings 256 in the encapsulant 25 and extend beyond the exterior surface of the external routing circuitry 26 in the upward direction.

In the face-to-face semiconductor assembly 530 of FIG. 54, the vertical connecting elements 24 include a combination of conductive vias 244, metal pillars 245 and solder balls 246. The metal pillars 245 contact the first conductive traces 215. The conductive vias 244 extend from the metal pillars 245 to the exterior conductive traces 262. The solder balls 246 contact the conductive vias 244 and fill up the remaining space of the via openings 256 in the encapsulant 25 and extend beyond the exterior surface of the external routing circuitry 26 in the upward direction.

### Embodiment 6

FIG. 55 is a cross-sectional view of yet another face-to-face semiconductor assembly in accordance with the sixth embodiment of the present invention.

In this embodiment, the face-to-face semiconductor assembly 610 is manufactured in a manner similar to that illustrated in Embodiment 3, except that the encapsulated device 20 includes no external routing circuitry 26 on the encapsulant 25 and the vertical connecting elements 24 are formed in different configuration.

The encapsulated device 20 is accomplished by deposition of solder balls 246 into the via openings 256 in the encapsulant 25 of FIG. 29 and then removal of the sacrificial carrier 10. As a result, the solder balls 246 contact the first routing circuitry 21 and fill up the via openings 256 of the encapsulant 25 to serve as vertical connecting elements 24.

The semiconductor assemblies described above are merely exemplary. Numerous other embodiments are contemplated. In addition, the embodiments described above can be mixed-and-matched with one another and with other embodiments depending on design and reliability considerations. The encapsulated device can include multiple first semiconductor chips and be electrically coupled to multiple second semiconductor chips, and the second semiconductor chip can share or not share the cavity with other second semiconductor chips. For instance, a cavity can accommodate a single second semiconductor chip, and the thermal board can include multiple cavities arranged in an array for multiple second semiconductor chips. Alternatively, numerous second semiconductor chips can be positioned within a single cavity. Additionally, an encapsulated device can share or not share the thermal board with other encapsulated devices. For instance, a single encapsulated device can be stacked on the thermal board. Alternatively, numerous encapsulated devices may be stacked on the thermal board. For instance, four encapsulated devices in a 2×2 array can be stacked on the thermal board and the optional second routing circuitry of the thermal board can include additional conductive traces to receive and route additional encapsulated devices. Likewise, a thermal board can share or not share the encapsulated device with other thermal boards.

As illustrated in the aforementioned embodiments, a distinctive face-to-face semiconductor assembly is configured and includes a first semiconductor chip, a first routing circuitry, an encapsulant, an array of vertical connecting elements, a second semiconductor chip, a thermal board, and an optional external routing circuitry. The first semiconductor chip is sealed in the encapsulant, whereas the second semiconductor chip is placed within a cavity of the thermal board and not sealed by an encapsulant. In the face-to-face semiconductor assembly of the present invention, a resin may be further provided to fill in a space between the first routing circuitry and the second semiconductor chip and between the first routing circuitry and the thermal board and fill up a gap in the cavity of the thermal board between the second semiconductor chip and the sidewalls of the cavity. For the convenience of below description, the direction in which the first surface of the encapsulant faces is defined as the first direction, and the direction in which the second surface of the encapsulant faces is defined as the second direction.

The first and second semiconductor chips each has an active surface facing the first routing circuitry and are face-to-face electrically connected to each other through the first routing circuitry therebetween. The first and second semiconductor chips can be packaged or unpackaged chips. For instance, the first and second semiconductor chips can be bare chips, or wafer level packaged dies, etc. Alternatively, the first and second semiconductor chips can be stacked-die chips. In a preferred embodiment, an encapsulated device having the first semiconductor chip electrically coupled to the first routing circuitry is prepared by the steps of: electrically coupling the first semiconductor chip to the first routing circuitry detachably adhered over a sacrificial carrier; providing the encapsulant and the vertical connecting elements over the first routing circuitry; and removing the sacrificial carrier from the first routing circuitry. By a well-known flip chip bonding process such as thermo-compression or solder reflow, the first semiconductor chip can be electrically coupled to the first routing circuitry using bumps without metallized vias in contact with the first semiconductor chip. Likewise, after removal of the sacrificial carrier, the second semiconductor chip can be electrically coupled to the first routing circuitry using bumps by a well-known flip chip bonding process without metallized vias in contact with the second semiconductor chip. Further, before the step of providing the encapsulant, a heat spreader may be attached to an inactive surface of the first semiconductor chip. As a result, the heat generated by the first semiconductor chip can be conducted away through the heat spreader.

The first routing circuitry can provides the shortest interconnection distance between the first and second semiconductor chips and preferably is a buildup circuitry without a core layer. Specifically, the first routing circuitry can be a multi-layer routing circuitry detachably adhered on the sacrificial carrier and include routing traces on the sacrificial carrier, a dielectric layer on the routing traces and the sacrificial carrier, and conductive traces that extend from selected portions of the routing traces and fill up via openings in the dielectric layer to form metallized vias and laterally extend on the dielectric layer. Accordingly, after removal of the sacrificial carrier, the routing traces and the dielectric layer can have exposed surfaces facing in the first direction and substantially coplanar with each other. Further, the first routing circuitry may include additional dielectric layers, additional via openings, and additional conductive traces if needed for further signal routing. In the present invention, the step of forming the first routing circuitry on the sacrificial carrier can be executed by directly forming the first routing circuitry on the sacrificial carrier, or by separately forming and then detachably adhering the first routing circuitry to the sacrificial carrier.

The sacrificial carrier, which provides rigidity support for the encapsulated device, can be detached from the first routing circuitry by a chemical etching process or a mechanical peeling process after the formation of the encapsulant. The sacrificial carrier may be made of any conductive or non-conductive material, such as copper, nickel, chromium, tin, iron, stainless steel, silicon, glass, graphite, plastic film, or other metal or non-metallic materials. For the aspect of detaching the sacrificial carrier by a chemical etching process, the sacrificial carrier typically is made of chemically removable materials. In consideration of the routing traces in contact with the sacrificial carrier not being etched during removal of the sacrificial carrier, the sacrificial carrier may be made of nickel, chromium, tin, iron, stainless steel, or any other material that can be removed using an etching solution inactive to the routing traces made of copper. Alternatively, the routing traces are made of any stable material against etching during removal of the sacrificial carrier. For instance, the routing traces may be gold pads in the case of the sacrificial carrier being made of copper. Additionally, the sacrificial carrier also can be a multi-layer structure having a barrier layer and a support sheet, and the first routing circuitry is formed on the barrier layer of the sacrificial carrier. As the first routing circuitry is spaced from the support sheet by a barrier layer disposed therebetween, the support sheet can be removed without damage on the routing traces of the first routing circuitry even the routing traces and the support sheet are made of the same material. The barrier layer may be a metal layer that is inactive against chemical etching during chemically removing the support sheet and can be removed using an etching solution inactive to the routing traces. For instance, the support sheet made of copper or aluminum may be provided with a nickel, chromium or titanium layer as the barrier layer on its surface, and the routing traces made of copper or aluminum are deposited on the nickel, chromium or titanium layer. Accordingly, the nickel, chromium or titanium layer can protect the routing traces from etching during removal of the support sheet. As an alternative, the barrier layer may be a dielectric layer that can be removed by, for example, a mechanical peeling or plasma ashing process. For instance, a release layer may be used as a barrier layer disposed between the support sheet and the first routing circuitry, and the support sheet can be removed together with the release layer by a mechanical peeling process.

The vertical connecting elements, extending through the encapsulant, can include metal pillars, solder balls, conductive vias or a combination thereof and provide electrical contacts for next-level connection. The vertical connecting elements can be formed to be electrically connected to the first routing circuitry before or after provision of the encapsulant. In a preferred embodiment, the vertical connecting elements are located at the peripheral area of the first routing circuitry and extend from the first routing circuitry to or beyond the second surface of the encapsulant in the second direction. As a result, the vertical connecting elements can have a first end in contact with the first routing circuitry and an opposite second end adjacent to the second surface of the encapsulant.

The thermal board includes a heat spreader and an optional second routing circuitry. The heat spreader can provide thermal dissipation for the second semiconductor chip attached to the heat spreader using a thermally conductive contact element, such as solder or organic resin having blended metal particles. The optional second routing circuitry laterally surrounds the second semiconductor chip and may be buildup circuitry. Preferably, the second routing circuitry is a multi-layered buildup circuitry and can include at least one dielectric layer and conductive traces that fill up via openings in the dielectric layer and extend laterally on the dielectric layer. The dielectric layer and the conductive traces are serially formed in an alternate fashion and can be in repetition when needed. For ground connection, the second routing circuitry can be electrically coupled to the heat spreader through metallized vias in contact with the hear spreader. In the aspect of the thermal board having no second routing circuitry on the heat spreader, the heat spreader has a cavity to accommodate the second semiconductor chip, and may be electrically coupled to the first routing circuitry of the encapsulated device for ground connection by, for example, bumps in contact with the heat spreader and the first routing circuitry. As for the alternative aspect of the thermal board having the second routing circuitry on the heat spreader, the cavity of the thermal board extends through the second routing circuitry to expose a selected portion of the heat spreader. In this alternative aspect, the second routing circuitry can be electrically coupled to the first routing circuitry by bumps, not by direct build-up process. Preferably, the bumps in contact with the second routing circuitry or the heat spreader have a height smaller than the combined height of the second semiconductor chip and the bumps in contact with the second semiconductor chip. More specifically, the combined height of the second semiconductor chip and the bumps in contact with the second semiconductor chip and the first routing circuitry may be substantially equal to the sum of the cavity depth plus the height of the bumps in contact with the thermal board and the first routing circuitry.

The optional external routing circuitry is formed over the second surface of the encapsulant and may be a buildup circuitry electrically coupled to the vertical connecting elements. More specifically, the encapsulated device can further include conductive traces that contact and are electrically connected to the vertical connecting elements in the encapsulant and laterally extending over the second surface of the encapsulant. Further, the external routing circuitry may be a multi-layer routing circuitry that include one or more dielectric layers, via openings in the dielectric layer, and additional conductive traces if needed for further signal routing. The outmost conductive traces of the external routing circuitry can accommodate conductive joints, such as solder balls, for electrical communication and mechanical attachment with for the next level assembly or another electronic device.

The term “cover” refers to incomplete or complete coverage in a vertical and/or lateral direction. For instance, in the cavity-up position, the heat spreader covers the second semiconductor chip in the downward direction regardless of whether another element such as the thermally conductive contact element is between the second semiconductor chip and the heat spreader.

The phrases “attached on” and “mounted on” includes contact and non-contact with a single or multiple element(s). For instance, the heat spreader is attached to the inactive surface of the second semiconductor chip regardless of whether it is separated from the second semiconductor chip by a thermally conductive contact element.

The phrases “electrical connection”, “electrically connected” and “electrically coupled” refer to direct and indirect electrical connection. For instance, the vertical connecting elements directly contact and are electrically connected to the first routing circuitry, and the second semiconductor chip is spaced from and electrically connected to the first routing circuitry by the first bumps.

The “first direction” and “second direction” do not depend on the orientation of the semiconductor assembly, as will be readily apparent to those skilled in the art. For instance, the first surface of the encapsulant faces the first direction and the second surface of the encapsulant faces the second direction regardless of whether the semiconductor assembly is inverted. Thus, the first and second directions are opposite one another and orthogonal to the lateral directions. Furthermore, the first direction is the upward direction and the second direction is the downward direction in the cavity-down position, and the first direction is the downward direction and the second direction is the upward direction in the cavity-up position.

The semiconductor assembly according to the present invention has numerous advantages. For instance, the first and second semiconductor chips are face-to-face mounted on opposite sides of the first routing circuitry, which can offer the shortest interconnect distance between the first and second semiconductor chips. The first routing circuitry provides primary fan-out routing/interconnection for the first and second semiconductor chips whereas the vertical connecting elements offer electrical contacts for external connection or next-level routing circuitry connection. As the first and second semiconductor chips are electrically coupled to the first routing circuitry by bumps, not by direct build-up process, the simplified process steps result in lower manufacturing cost. The external routing circuitry can provide terminal pads populated all over the area to increase external electrical contacts for next-level assembly. The heat spreader can provide thermal dissipation, electromagnetic shielding and moisture barrier for the second semiconductor chip, and also provides mechanical support for the encapsulated device stacked thereon. The semiconductor assembly made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A thermally enhanced face-to-face semiconductor assembly with a heat spreader, comprising:
an encapsulated device that includes a first semiconductor chip, an encapsulant, an array of vertical connecting elements, and a first routing circuitry disposed on a first surface of the encapsulant, wherein (i) the first semiconductor chip is embedded in the encapsulant and electrically coupled to the first routing circuitry, and (ii) the vertical connecting elements are laterally covered by the encapsulant and surround the first semiconductor chip, wherein the vertical connecting elements are electrically coupled to the first routing circuitry and extend to or extend beyond a second surface of the encapsulant opposite to the first surface; and
a thermally enhanced device that includes a heat spreader, a second routing circuitry disposed over the heat spreader, and a second semiconductor chip thermally conductible to the heat spreader by a thermally conductive contact element;
wherein the encapsulated device is stacked over the thermally enhanced device, with the second semiconductor chip electrically coupled to and spaced from the first routing circuitry by an array of first bumps and with the second routing circuitry electrically coupled to and spaced from the first routing circuitry by an array of second bumps.

2. The thermally enhanced face-to-face semiconductor assembly of claim 1, wherein the encapsulated device further includes an external routing circuitry disposed on the second surface of the encapsulant and electrically coupled to the vertical connecting elements in the encapsulant.

3. The thermally enhanced face-to-face semiconductor assembly of claim 1, wherein the vertical connecting elements include metal pillars, solder balls, conductive vias, or a combination thereof.

4. The thermally enhanced face-to-face semiconductor assembly of claim 1, wherein the second routing circuitry is further electrically coupled to the heat spreader.

5. The thermally enhanced face-to-face semiconductor assembly of claim 1, wherein the thermally conductive contact element includes solder or organic resin having blended metal particles.

6. The thermally enhanced face-to-face semiconductor assembly of claim 1, wherein the encapsulated device further includes another heat spreader that is attached to an inactive surface of the first semiconductor chip.

7. The thermally enhanced face-to-face semiconductor assembly of claim 1, further comprising a resin filled in the space between the encapsulated device and the thermally enhanced device.

8. A thermally enhanced face-to-face semiconductor assembly with a heat spreader, comprising:
an encapsulated device that includes a first semiconductor chip, an encapsulant, an array of vertical connecting elements, and a first routing circuitry disposed on a first surface of the encapsulant, wherein (i) the first semiconductor chip is embedded in the encapsulant and electrically coupled to the first routing circuitry, and (ii) the vertical connecting elements are laterally covered by the encapsulant and surround the first semiconductor chip, wherein the vertical connecting elements are electrically coupled to the first routing circuitry and extend to or extend beyond a second surface of the encapsulant opposite to the first surface; and
a thermally enhanced device that includes a heat spreader and a second semiconductor chip thermally conductible to the heat spreader by a thermally conductive contact element and located in a cavity of the heat spreader,
wherein the encapsulated device is stacked over the thermally enhanced device, with the second semiconductor chip electrically coupled to and spaced from the first routing circuitry by an array of bumps.

9. The thermally enhanced face-to-face semiconductor assembly of claim 8, wherein the encapsulated device further includes an external routing circuitry disposed on the second surface of the encapsulant and electrically coupled to the vertical connecting elements in the encapsulant.

10. The thermally enhanced face-to-face semiconductor assembly of claim 8, wherein the vertical connecting elements include metal pillars, solder balls, conductive vias, or a combination thereof.

11. The thermally enhanced face-to-face semiconductor assembly of claim 8, wherein the encapsulated device further includes another heat spreader that is attached to an inactive surface of the first semiconductor chip.

12. The thermally enhanced face-to-face semiconductor assembly of claim 8, further comprising a resin filled in a space between the encapsulated device and the thermally enhanced device.

13. A method of making a thermally enhanced face-to-face semiconductor assembly with a heat spreader, comprising:
providing an encapsulated device that includes a first semiconductor chip, an encapsulant, an array of vertical connecting elements and a first routing circuitry disposed on a first surface of the encapsulant, wherein (i) the first semiconductor chip is embedded in the encapsulant and electrically coupled to the first routing circuitry, and (ii) the vertical connecting elements surround the first semiconductor chip and are electrically coupled to the first routing circuitry;
electrically coupling a second semiconductor chip to the first routing circuitry of the encapsulated device through an array of first bumps at the first routing circuitry;
providing a thermal board that includes a heat spreader; and
stacking the encapsulated device over the thermal board, with the second semiconductor chip thermally conductible to the heat spreader by a thermally conductive contact element.

14. The method of claim 13, wherein the thermal board further includes a second routing circuitry over the heat spreader, and the step of stacking the encapsulated device on the thermal board includes electrically coupling the second routing circuitry to the first routing circuitry through an array of second bumps at the first routing circuitry.

15. The method of claim 13, wherein the step of providing the encapsulated device includes:
providing the first routing circuitry detachably adhered over a sacrificial carrier;
electrically coupling the first semiconductor chip to the first routing circuitry;
providing the encapsulant that laterally surrounds the first semiconductor chip and covers the first routing circuitry;
forming the vertical connecting elements; and
removing the sacrificial carrier from the first routing circuitry.

16. The method of claim 13, wherein the encapsulated device further includes an external routing circuitry disposed on a second surface of the encapsulant opposite to the first surface and electrically coupled to the vertical connecting elements in the encapsulant.

17. The method of claim 16, wherein the step of providing the encapsulated device includes:
providing the first routing circuitry detachably adhered over a sacrificial carrier;
electrically coupling the first semiconductor chip to the first routing circuitry;
providing the encapsulant that laterally surrounds the first semiconductor chip and covers the first routing circuitry;
forming the vertical connecting elements;
forming the external routing circuitry on the second surface of the encapsulant, with the external routing circuitry electrically coupled to the vertical connecting elements; and
removing the sacrificial carrier from the first routing circuitry.

18. The method of claim 13, wherein the encapsulated device further includes another heat spreader that is attached to an inactive surface of the first semiconductor chip.

19. The method of claim 14, wherein the second routing circuitry is further electrically coupled to the heat spreader.

20. The method of claim 13, further comprising a step of providing a resin filled in a space between the encapsulated device and the thermal board and between the encapsulated device and the second semiconductor chip.
